(19) United States
(12) Patent Application Publication
(10) Pub. No.: US 2012/0081348 A1
(43) Pub. Date: Apr. 5, 2012

(54) METHOD FOR ELIMINATING ROW OR COLUMN ROUTING ON ARRAY PERIPHERY

(75) Inventor: Yeh-Jiun Tung, Sunnyvale, CA (US)

(73) Assignee: QUALCOMM MEMS Technologies, Inc., San Diego, CA (US)

(21) Appl. No.: 12/898,499

(22) Filed: Oct. 5, 2010

(51) Int. Cl. G06F 3/038; H05K 3/00; G02B 26/02

(52) U.S. Cl. 345/211; 359/291; 359/290; 216/17; 216/13

(57) ABSTRACT

The present disclosure provides systems, methods, and apparatus to facilitate edge routing among a plurality of microelectromechanical devices arranged in a mosaic or array. In one aspect, the disclosed implementations modify the construction of a movable layer, such that portions of the movable layer, in addition to serving their original functions, also facilitate routing from a single edge of the device. In some implementations, portions of the movable layer are re-oriented to achieve edge routing, while in others, the orientation remains the same but electrical connections are altered.

### TECHNICAL FIELD

This disclosure relates to an improved routing structure for an array of interferometric devices and generally to electromechanical systems and display devices.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a metallic membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in a device including an array having a plurality of electromechanical elements arranged in columns and rows. The array itself may include a plurality of fixed electrodes, each fixed electrode spanning a row of elements of the array and forming a portion of the electromechanical elements that the fixed electrode spans. The array may also include a plurality of first movable electrodes, each first movable electrode spanning a column of elements of the array and forming a portion of the electromechanical elements that the first movable electrode spans. The array may also include a plurality of second movable electrodes, each second movable electrode spanning a row of electromechanical elements of the array and forming a portion of the electromechanical elements that the second movable electrode spans, and each second movable electrode electrically connected to at least one first movable electrode. The device may also include a dielectric layer between at least a portion of the first movable electrodes and at least a portion of the second movable electrodes. The device may further include a row signal interface to provide drive signals to rows of elements in the array. The row signal interface may be disposed along a first side of the array and in communication with the plurality of fixed electrodes. The device may additionally include a column signal interface to provide drive signals to columns of elements in the array; the column signal interface disposed along the first side of the array and in communication with the plurality of second movable electrodes.

In some implementations, the electromechanical device may be an interferometric modulator. Additionally, each second movable electrode may be aligned orthogonal to each first movable electrode and each second movable electrode may be electrically connected to at least one first movable electrode through a via in a portion of a sacrificed pixel. The electromechanical device may include a substrate which expands as it is heated. The materials including a movable electrode, dielectric layer, and a second movable electrode may also be selected so as to expand when heated in a manner substantially similar to the substrate.

Some implementations contemplate a device that includes an array having a plurality of electromechanical elements arranged in columns and rows. The array may include a plurality of fixed electrodes, each fixed electrode spanning a row of electromechanical elements of the array and forming a portion of the electromechanical elements that the fixed electrode spans. The device may also include a plurality of first movable electrodes, each first movable electrode spanning a column of electromechanical elements of the array and forming a portion of the electromechanical elements that the first movable electrode spans. The device may also include a plurality of second movable electrodes, each second movable electrode spanning a column of electromechanical elements of the array and forming a portion of the electromechanical elements that the second movable electrode spans. Each second movable electrode may be electrically connected to at least one fixed electrode. The device may further include a dielectric layer between at least a portion of the first movable electrodes and at least a portion of the second movable electrodes. The device may also include a column signal interface to provide drive signals to columns of elements in the array. The column signal interface disposed along a first side or the array and in communication with the plurality of first movable electrodes. The device may further include a row signal interface to provide drive signals to rows of elements in the array. The row signal interface disposed along the first side of the array and in communication with the plurality of second movable electrodes.

In some implementations, the electromechanical device can be an interferometric modulator. Additionally, each second movable electrode can be aligned parallel to each first movable electrode. Each second movable electrode can be electrically connected to at least one fixed electrode through a via in the dielectric and first movable layers. In some implementations, the via can be formed through a dielectric layer. In some implementations, the first plurality of movable electrodes are not in electrical communication with any of the second plurality of movable electrodes.

Some implementations contemplate an electromechanical device, including a fixed electrode forming a portion of the electromechanical device, the fixed electrode further in communication with a row signal interface along a first side of the array. The device may further include a first movable electrode forming a portion of the electromechanical device and a second movable electrode forming a portion of the electromechanical device. The second movable electrode may be electrically connected to the first movable electrode, the second movable electrode further in communication with a column signal interface along the first side of the array. The device may also include a dielectric layer between at least a portion of the first movable electrode and at least a portion of the second movable electrode.

In some implementations, an electromechanical device includes a first fixed means for conducting forming a portion of the electromechanical device, the fixed conducting means further in communication with a first means for interfacing along a first side of a means for displaying. The device may further include a first movable means for conducting forming a portion of the electromechanical device and a second movable conducting means forming a portion of the electromechanical device. The second movable conducting means may be electrically connected to the first movable conducting means, the second movable conducting means further in communication with a second signal interface along the first side of the displaying means. The device may also include a means for electrical insulation between at least a portion of the first movable conducting means and at least a portion of the second movable conducting means.

In some implementations, a method of manufacturing an edge-controlled display includes providing a substrate, providing a first interface along a side of the display, providing a second interface along the side of the display, forming a fixed electrode layer over the substrate and etching the first fixed electrode layer to form a plurality of electrically separate strips of the fixed electrode layer wherein the plurality of electrically separate strips are in electrical communication with the first interface; forming posts extending above the first fixed electrode, forming a first movable electrode layer over the posts, including etching a plurality of electrically separate strips of the first movable electrode layer, forming a dielectric layer over the first movable electrode layer, including etching vias through the dielectric layer, forming a second movable electrode layer over the dielectric layer, including etching a plurality of electrically separate strips of the second movable electrode layer, wherein each of the plurality of electrically separate strips of the second movable layer are separately in electrical communication with an electrically separate strip of the first movable electrode and with the second interface.

In some implementations, the plurality of electrically separate strips of the second movable electrode layer may be substantially orthogonal to the plurality of electrically separate strips of the first movable electrode layer. Additionally, forming the movable electrode layer includes forming extensions and recesses, the extensions in communication with at least one via.

Some implementations contemplate a method of manufacturing an edge-controlled display. These implementations include providing a substrate, providing a first interface along a side of the display; providing a second interface along the side of the display, forming a fixed electrode layer over the substrate and etching the first fixed electrode layer to form a plurality of electrically separate strips of the fixed electrode layer. The method may further include forming posts extending above the first fixed electrode and forming a first movable electrode layer over the posts, including etching a plurality of electrically separate strips of the first movable electrode layer. The electrically separate strips of the first movable layer may be in electrical communication with the second interface; forming a dielectric layer over the first movable electrode layer, including forming vias in the dielectric layer. A second movable electrode layer can be formed over the dielectric layer, including etching a plurality of electrically separate strips of the second movable electrode layer, wherein each of the plurality of electrically separate strips of the second movable electrode layer are separately in electrical communication with an electrically separate fixed electrode strip and in electrical communication with the first interface.

In some implementations, a first mask used to etch the plurality of electrically separate strips of the first movable electrode layer may be different from a second mask used to etch the plurality of electrically separate strips of the second movable electrode layer. In addition, the first mask can produce extensions and recesses in the first movable electrode layer. Also, the thermal coefficient of expansion of the substrates can be substantially the same as the thermal coefficient of expansion of at least one of the first movable electrode, dielectric layer, and second movable electrode together.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3A shows an example of a diagram illustrating movable reflective layer position versus applied voltage for the interferometric modulator of FIG. 1.

FIG. 3B shows an example of a table illustrating various states of an interferometric modulator when various common and segment voltages are applied.

FIG. 4A shows an example of a diagram illustrating a frame of display data in the 3×3 interferometric modulator display of FIG. 2.

FIG. 4B shows an example of a timing diagram for common and segment signals that may be used to write the frame of display data illustrated in FIG. 4A.

FIG. 5A shows an example of a partial cross-section of the interferometric modulator display of FIG. 1.

FIGS. 5B-5E show examples of cross-sections of varying implementations of interferometric modulators.

FIG. 6 shows an example of a flow diagram illustrating a manufacturing process for an interferometric modulator.

FIGS. 7A-7E show examples of cross-sectional schematic illustrations of various stages in a method of making an interferometric modulator.

FIG. 8A is a top plan view schematic illustrating an array having routing interfaces along both a first and second edge.

FIG. 8B is a top plan view schematic illustrating an array having routing interfaces along a single edge.

FIGS. 9A through 9J are schematic cross-sections of an interferometric modulator illustrating a manufacturing process according to certain implementations.

FIG. 10A is a perspective schematic of a portion of an interferometric array illustrating a movable mechanical layer that includes three aligned layers.

FIG. 10B is a perspective schematic of a portion of an interferometric array illustrating a first implementation for routing along a single edge, wherein the cap layers 36a-c are not aligned with the mirror layers 14a-c.

FIG. 11 illustrates two photolithographic masks which can be used to produce the movable mechanical layers that are illustrated in FIG. 10B.

FIG. 12 illustrates a schematic cross-section of an implementation of the interconnection between the cap layer and the mirror layer shown at 1901a in FIG. 10B with a via through the dielectric layer.

FIG. 13 illustrates a schematic cross-section of another implementation of the interconnection between the cap layer and the mirror layer shown at 1901a in FIG. 10B with a via through the dielectric layer.

FIG. 14 illustrates a top plan view of the support layer post deposition in the array after etching, including support layer material that is used to protect the underlying sacrificial material during formation of the interconnection 1901a.

FIG. 15 illustrates a cross-sectional view of the interconnect structure along line 3200 of FIG. 14.

FIG. 16 is a flow chart illustrating one implementation of a manufacturing process for an interferometric modulator array as shown in FIGS. 9A-9J, with interconnects as shown in FIG. 12.

FIG. 17 is a flow chart illustrating one implementation of a manufacturing process for an interferometric modulator array as shown in FIGS. 9A-9J, with interconnects as shown in FIG. 13.

FIG. 18 is a perspective schematic of a portion of an interferometric array illustrating a second implementation for routing along a single edge, wherein the cap layers 36a-c are in communication with fixed electrodes 17a-c respectively.

FIG. 19 is a schematic cross-section illustrating an implementation of the connection between the cap layer 36 and the fixed electrode 16b shown at 1901a in FIG. 10A, the connection being a via that is disposed through the dielectric and mirror layers.

FIG. 20 is a flow chart illustrating one implementation of a manufacturing process for an interferometric modulator array as shown in FIG. 18, with interconnects as shown in FIG. 19.

FIG. 21 illustrates a top-down, magnified view of a post in an array, showing the exposed portions of the post in relation to the mechanical layer depositions after completing certain of the deposition processes described in the above figures.

FIG. 22 is a schematic illustrating a top plan view of an alternative routing configuration at intersections 1901a-c in the configuration of FIG. 10B.

FIG. 23 is a schematic illustrating a perspective view schematic of the proposed routing structure of the intersection of FIG. 22, wherein the cap 36a-c and dielectric 35a-c layers have been raised to more clearly illustrate the structure of the mirror layers 14a-c.

FIGS. 24A and 24B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

An array of MEMS devices may include rows and columns of individual elements which may be actuated via row and column interfaces. While effective in some implementations, arrays having interfaces at two separate locations may have an adverse impact on the overall design. For example, interfaces on perpendicular sides of the array may be bulky and unsuitable for some applications. Driver chips attached to the interfaces may be rigid and thus prone to breakage if flexed. Also, including drivers on two edges of the array may take up significant surface area. Furthermore, when designing a physically flexible display, disposing inflexible driver chips along two or more edges of the display may compromise the functionality of a flexible substrate. The present implementations therefore provide useful and novel means for routing row and column control signals along a single edge, which can obviate the aforementioned design concerns.

Certain implementations disclose using a conductive upper or “cap” layer to facilitate routing electrical drive signals to array display elements from a single edge of the array. Though referred to in some instances as “row” or “column” routing, a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). Unless explicitly stated otherwise, the terms “array” and “mosaic” may refer to either configuration. Thus, although the display may be referred to as including an “array” or “mosaic,” the elements themselves need not be arranged orthogonally to one another, or disposed in an even distribution, in any instance, but may include arrangements having asymmetric shape and unevenly distributed elements.

One example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

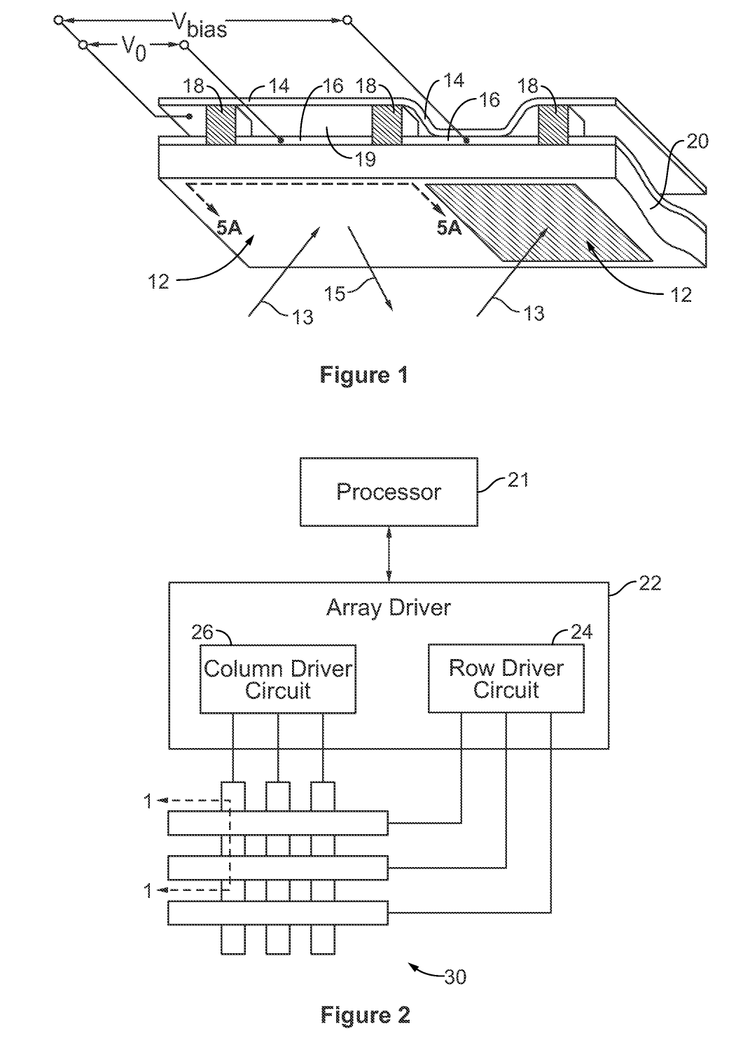

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by a person having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 um, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14a remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

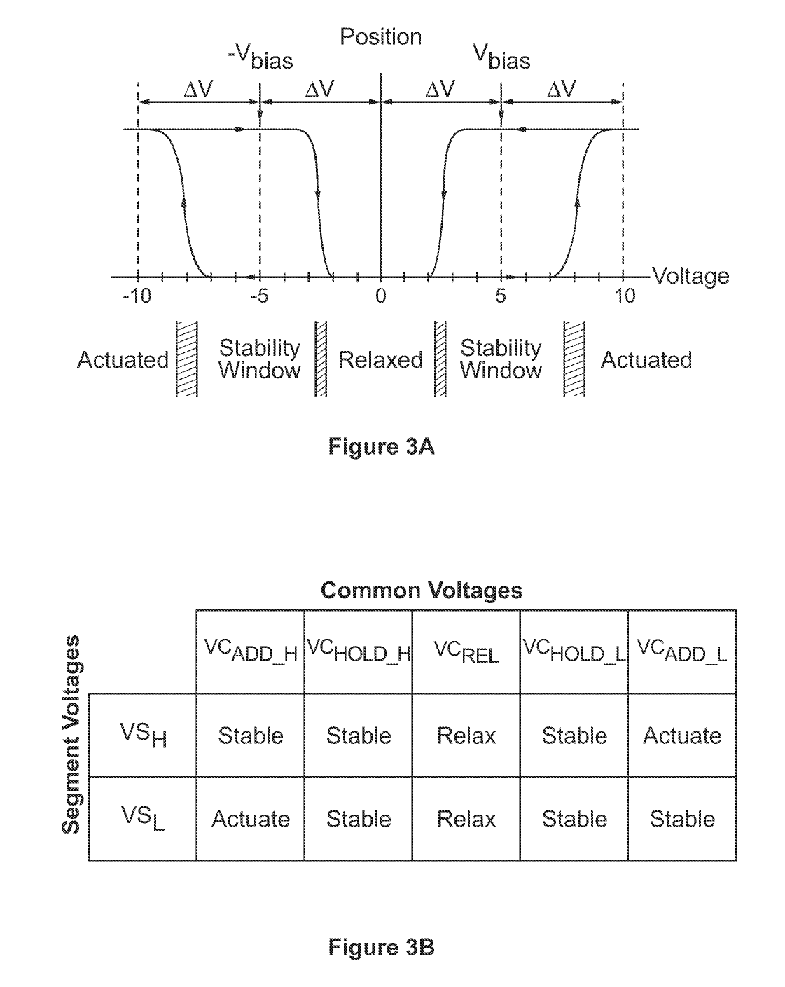

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

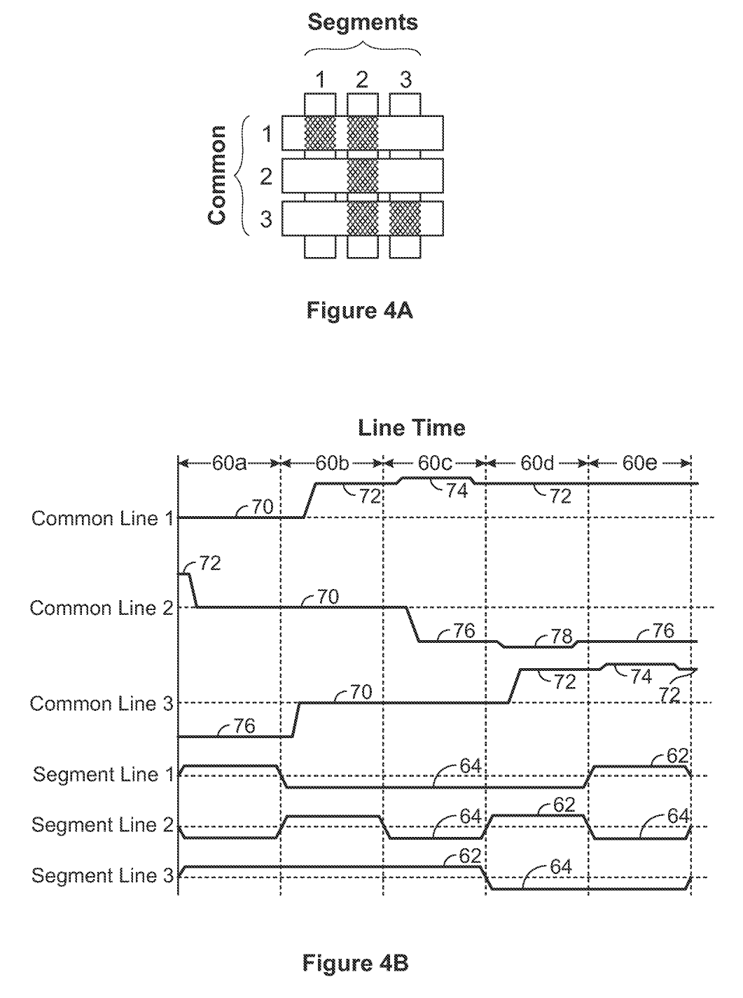

FIG. 3A shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3A. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3A, exists where there is a window of applied voltage within which the device is stable in either the relaxed or actuated state. This is referred to herein as the “hysteresis window” or “stability window.” For a display array 30 having the hysteresis characteristics of FIG. 3A, the row/column write procedure can be designed to address one or more rows at a time. During the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts, and they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 3B shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

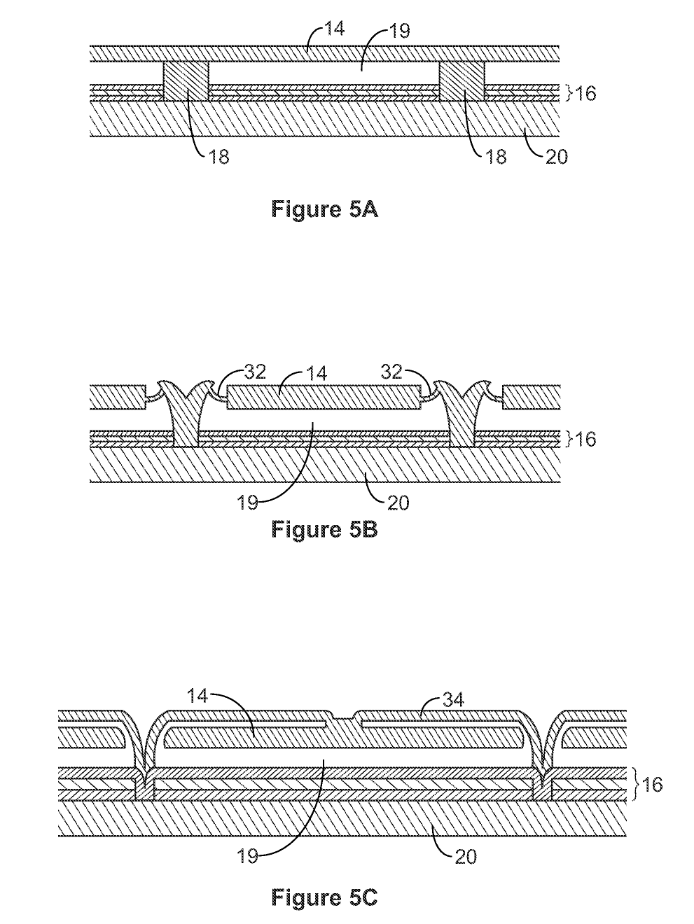

As illustrated in FIG. 3B (as well as in the timing diagram shown in FIG. 4B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3A, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 4A shows an example of a diagram illustrating a frame of display data in the 3×3 interferometric modulator display of FIG. 2. FIG. 4B shows an example of a timing diagram for common and segment signals that may be used to write the frame of display data illustrated in FIG. 4A. The signals can be applied to the, e.g., 3×3 array of FIG. 2, which will ultimately result in the line time 60e display arrangement illustrated in FIG. 4A. The actuated modulators in FIG. 4A are in a dark-state, i.e., where a substantial portion of the reflected light is outside of the visible spectrum so as to result in a dark appearance to, e.g., a viewer. Prior to writing the frame illustrated in FIG. 4A, the pixels can be in any state, but the write procedure illustrated in the timing diagram of FIG. 4B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 3B, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 4A, and will remain in that state as long as the hold voltages are applied along the common lines, regardless of variations in the segment voltage which may occur when modulators along other common lines (not shown) are being addressed.

In the timing diagram of FIG. 4B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 4B. In some other implementations, voltages applied along common lines or segment lines may vary to account for variations in the actuation and release voltages of different modulators, such as modulators of different colors.

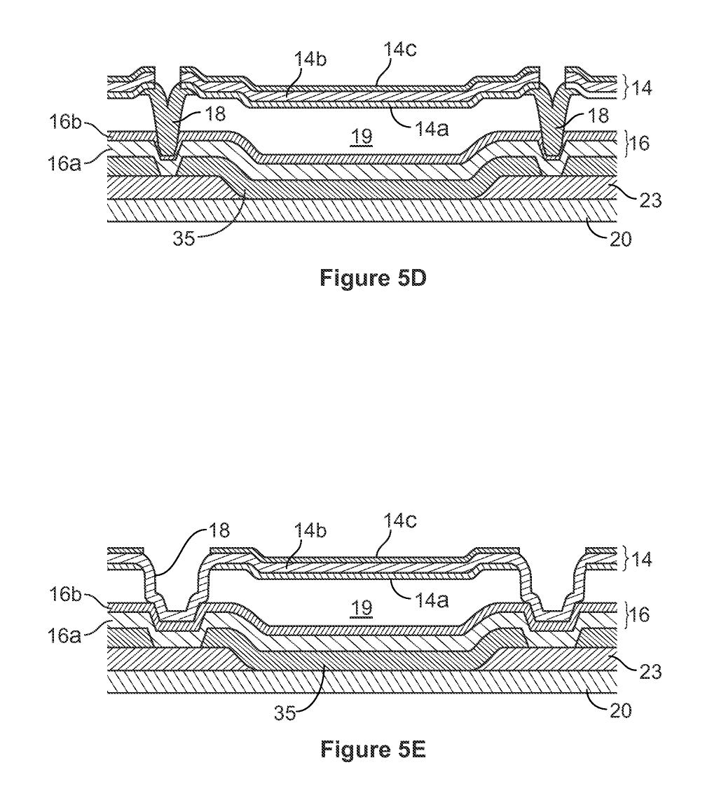

The details of the structure of interferometric modulators that operate in accordance with the principles set forth above may vary widely. For example, FIGS. 5A-5E show examples of cross-sections of varying implementations of interferometric modulators, including the movable reflective layer 14 and its supporting structures. FIG. 5A shows an example of a partial cross-section of the interferometric modulator display of FIG. 1, where a strip of metal material, i.e., the movable reflective layer 14 is deposited on supports 18 extending orthogonally from the substrate 20. In FIG. 5B, the movable reflective layer 14 of each IMOD is generally square or rectangular in shape and attached to supports at or near the corners, on tethers 32. In FIG. 5C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 5C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 5D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an Al alloy with about 0.5% Cu, or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 5D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, CF₄ and/or O₂ for the MoCr and SiO₂ layers and Cl₂ and/or BCl₃ for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 5E shows another example of an IMOD, where the movable reflective layer 14 is self supporting. In contrast with FIG. 5D, the implementation of FIG. 5E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 5E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 5A-5E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 5C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 5A-5E can simplify processing, such as (e.g., patterning).

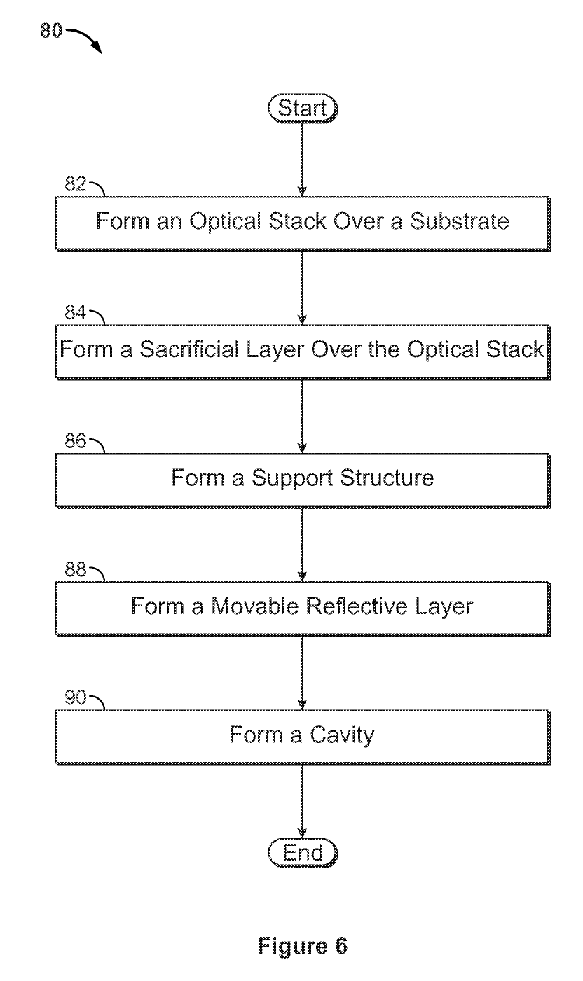

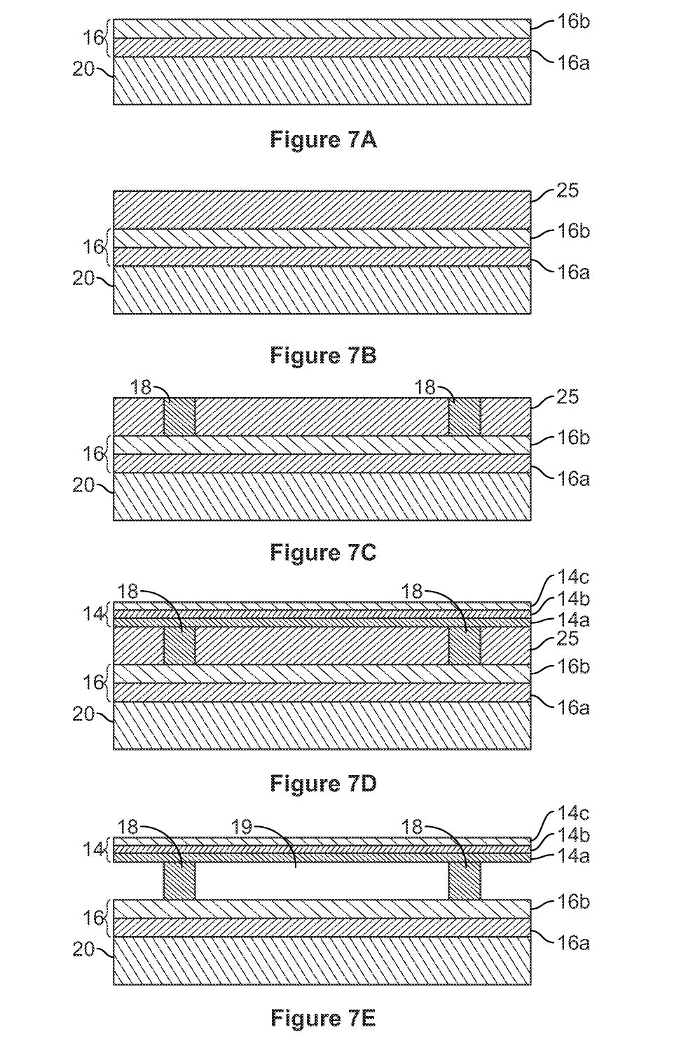

FIG. 6 shows an example of a flow diagram illustrating a manufacturing process 80 for an interferometric modulator, and FIGS. 7A-7E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 5, in addition to other blocks not shown in FIG. 6. With reference to FIGS. 1, 5 and 6, the process 80 begins at block 82 with the formation of the optical stack 16 over the substrate 20. FIG. 7A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 7A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 7B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 7E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 5 and 7C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 5A. Alternatively, as depicted in FIG. 7C, the aperture formed in the sacrificial layer 25 can extend through the sacrificial layer 25, but not through the optical stack 16. For example, FIG. 7E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 7C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 5 and 7D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 7D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 5 and 7E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

The depositions and etchings described above with reference to FIGS. 7A-7E may produce an array of interferometric modulators. However, each interferometric modulator in the array may be substantially identical, and routing along a single edge may not be feasible.

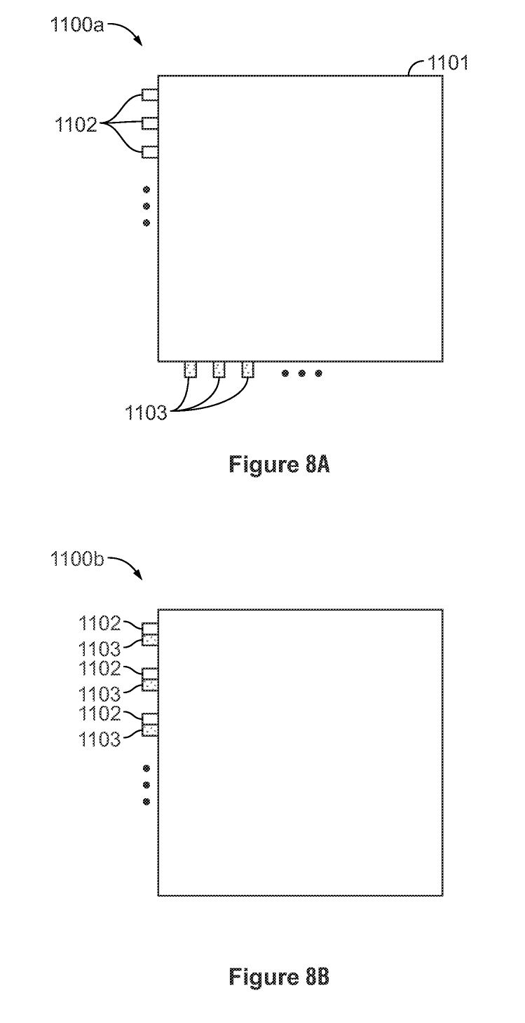

FIG. 8A illustrates a top-down perspective of an array having routing interfaces along both a first and second edge, and FIG. 8B illustrates a top-down perspective of an array having routing interfaces along a single edge. An array 1101 of interferometric modulators, or other MEMS device, as shown in configuration 1100a, will include rows and columns of individual elements which may be actuated via row 1102 and column 1103 interfaces. While effective, these interfaces may be connected to bulky drivers which are unsuitable for many applications. The present implementations therefore provide useful and novel means for instead routing along a single edge as shown in the configuration 1100b in FIG. 8B. Particularly, certain implementations disclose innovative uses of the conductive “cap” layer, so as to facilitate routing from a single edge. Though referred to in some instances as “row” or “column” routing, one will readily understand that referring to one direction as a “row” and another as a “column” is arbitrary. Similarly, as discussed above, though the display is referred to as including an “array,” the elements themselves need not be arranged orthogonally to one another, or in even distribution, but may include mosaics having asymmetric shape and unevenly distributed elements. One will recognize that each of 1102 and 1103 are examples of means for interfacing a signal. The entire array of elements 1101 may comprise a means for displaying.

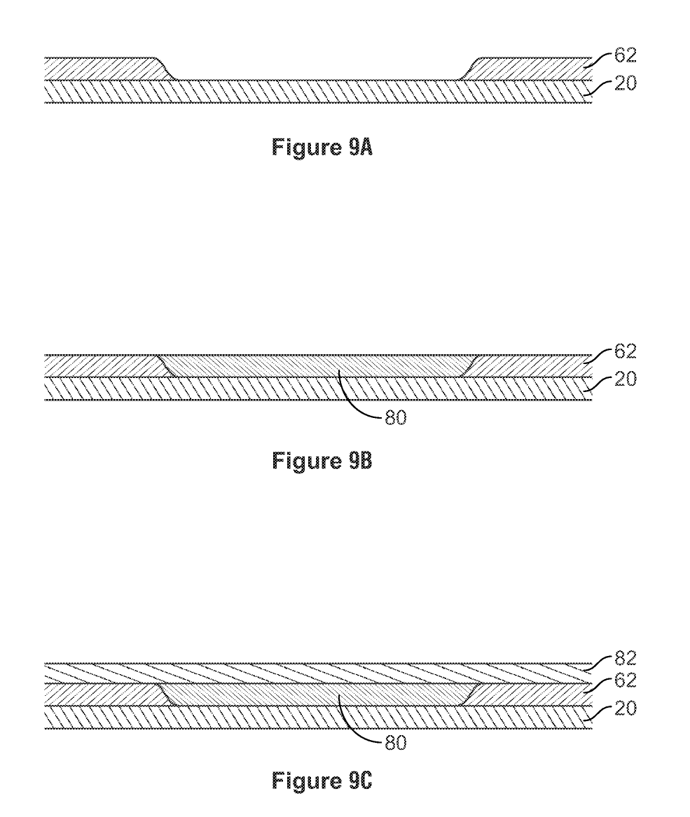

FIGS. 9A through 9J are schematic cross-sections of an interferometric modulator illustrating a manufacturing process according to certain implementations, which will permit routing along a single edge of the array. While particular parts and steps are described as suitable for interferometric modulator implementation, it will be understood that for other electromechanical systems implementations, different materials can be used or parts modified, omitted or added.

In FIG. 9A, a black mask structure 62 has been provided on a substrate 20. The substrate 20 can be comprised of a variety of materials, including glass or a transparent polymeric material which permits images to be viewed through the substrate 20. The black mask structure 62 can be configured to absorb ambient or stray light in optically inactive regions (e.g., beneath supports or posts, or between pixels) to improve the optical properties of a display device by increasing the contrast ratio. Additionally, in some implementations the black mask structure 62 can be conductive and be configured to function as an electrical bussing layer. In one implementation, the row electrodes are connected to the black mask structure 62 to reduce the resistance of the connected row electrode.

The black mask structure 62 can be formed using a variety of methods, including deposition and patterning techniques as described above with reference to FIGS. 7A-7E. The black mask structure 62 can include one or more layers. In one implementation, the black mask structure 62 includes a molybdenum-chromium (MoCr) layer that serves as an optical absorber, a transparent layer, e.g., a SiO₂ layer, and an aluminum alloy that serves as a reflector and a bussing layer, which may have a thickness in the range of approximately 30-80 Å, 500-1000 Å, and 500-5000 Å, respectively. The layers can be patterned using a variety of techniques, including photolithography and a dry etch including, for example, CF₄ and/or O₂ for the MoCr and SiO₂ layers and Cl₂ and/or BCl₃ for the aluminum alloy layer.

FIG. 9B illustrates providing a shaping structure 80 over the substrate 20. The shaping structure 80 may include a buffer oxide, such as SiO₂, which aids in maintaining a relatively planar profile across the substrate by filling in gaps between bussing or black mask structures 62. In one implementation, the shaping structure 80 has a thickness in the range of about 100-6000 Å. The thickness of the shaping structure 80 can be selected to produce stresses in the unreleased mechanical layer that produce a desired launch height (i.e., the height of the mechanical layer when unperturbed by the electrical force of the electrodes) upon release. As described above, the thickness needed for the sacrificial layer for a given desired gap height can be controlled by adjusting the launch height of the mechanical layer upon release, which in turn can be affected by the shaping structure 80. The sacrificial layer thickness can be selected so that it may be easily deposited. In some implementations, the sacrificial layer thickness may also be selected so as to produce a bending height of the mechanical layer 34. A large bending height of the mechanical layer can increase the brightness of the portion of the mechanical layer out of contact with the optical stack 16 during actuation, thereby degrading the black state and reducing the display's contrast ratio, gamut and color saturation. The shaping structure 80 can be formed using a variety of techniques, such as by deposition and patterning.

FIG. 9C illustrates providing and patterning a dielectric structure 82. The dielectric structure 82 can include, for example, SiON and/or another dielectric material such as a silicon nitride or silicon oxide. In one implementation, the thickness of the dielectric structure 82 is in the range of approximately 3000-5000 Å. However, as skilled artisans will recognize, the dielectric structure 82 can have a variety of thicknesses depending on the desired optical properties. In some implementations, a portion of the dielectric structure 82 can be removed above the black mask structure 62, such as to permit routing and row electrode layers to reach the black mask structure 62. In such an implementation, the black mask structure 62 can be implemented to serve bus signals.

FIG. 9D illustrates providing an optical stack 16 over the dielectric structure 82. As described above with reference to FIG. 1, the optical stack 16 may include several layers, which can include an optional transparent conductor, such as indium tin oxide (ITO), a partially reflective optical absorber layer 16b, such as chromium, and a transparent dielectric 16a. In one implementation, the optical stack 16 can include a MoCr layer having a thickness in the range of about 30-80 Å, an AlOₓ layer having a thickness in the range of about 50-150 Å, and a SiO₂ layer having of thickness in the range of about 250-500 Å. The separate transparent conductor can be omitted in favor of employing the black mask structure 62 to bus signals among pixels of the array, such that the thin, semi-transparent absorber layer 16b serves to provide conductivity sufficient for the optical stack 16 to serve as the stationary electrode for the electrostatic operation. Thus, the optical stack 16 can be electrically conductive, partially transparent and partially reflective. The absorber layer 16b can be formed from a variety of materials that are partially reflective such as various metals, semiconductors, and dielectrics. The partially reflective layer can be formed of one or more layers, and each of the layers can be formed of a single material or a combination of materials. In some implementations, the layers of the optical stack 16 are patterned into parallel strips, and may form row/column electrodes in a display device as described above with reference to FIG. 1. One or more layers of the optical stack 16 may physically and electrically contact the black mask 62. In many implementations, the optical stack 16 will include a dielectric 16a insulating the electrode 16b.

FIGS. 9E-9F illustrate providing and patterning a sacrificial layer 84 over the optical stack 16. The sacrificial layer 84 may later be removed to form a gap (e.g., gap 19 of FIG. 1). The formation of the sacrificial layer 84 over the optical stack 16 can include a deposition step. Additionally, the sacrificial layer 84 can be selected to include more than one layer, or include a layer of varying thickness, to aid in the formation of a display device having a multitude of resonant optical gaps. In an IMOD array, different gap sizes can represent different reflected colors. Moreover, in some implementations, multiple layers serving different functions can be provided, over or between sacrificial layers (e.g., the moveable reflective layer 14 in FIG. 7D may be created by placing sacrificial layers above and below the reflective layer 14 during deposition). As illustrated in FIG. 9F, the sacrificial layer 84 may be patterned to form vias 83 so as to aid in the formation of support posts.

FIGS. 9G and 9H illustrate providing and patterning a support layer 85 to form the support posts 60. The support layer 85 may include, for example, SiO₂ and/or SiON, and the support layer 85 may be patterned to form the support posts 60 in the vias 83 by a variety of techniques, such as using a dry etch including CF₄.

FIGS. 9I and 9J illustrate providing a mechanical layer 34 over the sacrificial layer 84 and patterning the mechanical layer 34. Skilled artisans will appreciate that the mechanical layer 34 can include a variety of layers, depending upon the electromechanical systems device functions. For example, the mechanical layer can be configured to function as the moveable electrode (e.g., FIG. 7A) or to support a moveable electrode (e.g., FIG. 7D). As illustrated in FIGS. 9I and 9J, the mechanical (or movable) layer 34 can include more than one layer, for example, a conductive layer 36, also referred to as a “cap layer” or simply a “cap,” a support layer 35, and a moveable reflective layer 14. Each of the cap 36 and reflective 14 layers may comprise movable means for conducting. In one implementation, the support layer 35 is a dielectric layer of, for example, SiON. The moveable reflective layer 14 and the conductive layer 36 can include, e.g., metallic materials (e.g., aluminum-copper (AlCu) with about 0.5% Cu by weight) and can be implemented as conductors. Having conductive structures above and below the dielectric support layer 35 can balance stresses and provide enhanced conduction (e.g., by possessing similar or identical coefficients of thermal expansion). Dielectric support layer 35 may comprise a means for electrical insulation.

FIG. 9J illustrates an interferometric device after patterning of the mechanical layer 34 and removal of the sacrificial layer 84. After removal of the sacrificial layer, the mechanical layer 34 may become displaced from the substrate 20 by a launch height and can change shape or curvature due to a variety of reasons, such as mechanical stresses.

The sequence and drawings have been simplified to omit some details not relevant to the principles and advantages taught herein. For example, in a color interferometric display system, different devices may have different gap sizes to interferometrically enhance a variety of colors, for example, red, green, and blue. Similarly, for example, three different mechanical layer materials or thicknesses can be employed to allow use of the same actuation voltage for collapsing the mechanical layer in three different gap sizes.

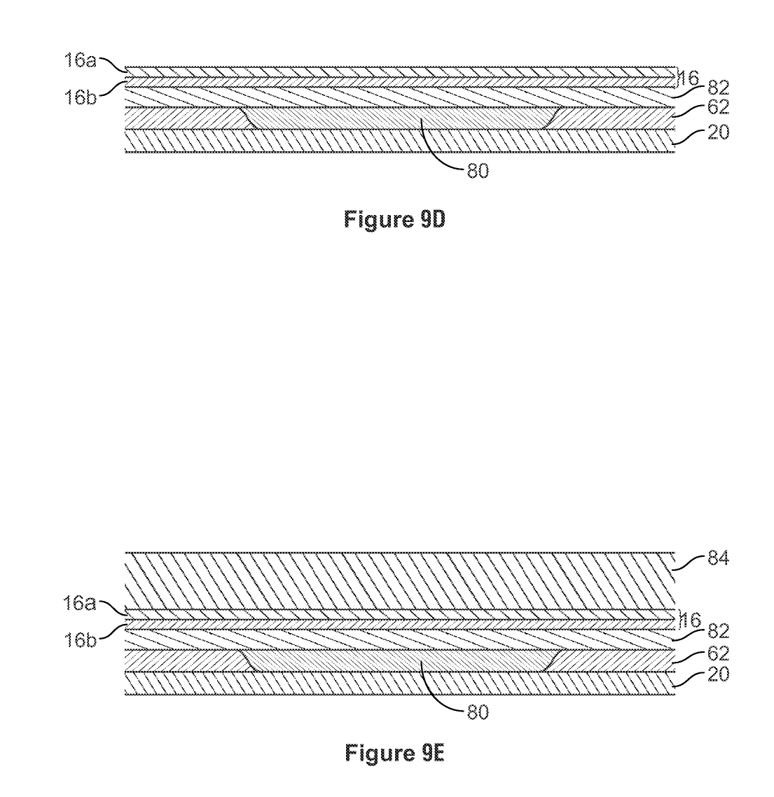

FIG. 10A is a perspective schematic of a portion of an interferometric array illustrating a movable mechanical layer including three aligned layers. FIG. 10A illustrates a simplified perspective view of an array of devices produced in the manner described with regard to FIGS. 9A-9J (for example, certain layers and features have been removed for clarity). FIGS. 10A-10B illustrate the movable layer above the substrate 20 (a viewer would be looking “up” into the display in FIGS. 10A-10B).

Configuration 1200a in FIG. 10A illustrates a mechanical layer 34 that includes at least three layers which are all aligned in the same direction: a metal mirror layer 14a (or reflective layer), a dielectric layer 35a disposed on the mirror layer 14a, and a metal “cap” layer 36a disposed on the dielectric layer 35a. The mirror layer 14a, may serve as a “column electrode” while electrode 17a found in the optical stack 16, serves as a “row electrode” (compare, e.g., with rows and columns of FIGS. 1 and 2). The electrode 17a is an example of a fixed means for conducting a signal. The dielectric layer 35a can prevent an electrical connection between the conductive mirror layer 14a and the cap layer 36a. The coefficient of thermal expansion of the cap layer 36a can be substantially the same, or identical, to the coefficient of thermal expansion of the mirror layer 14a. In some implementations, the dielectric 35a is at least partially removed at one or more locations so that the cap layer 36a is in electrical communication with the mirror layer 14a to avoid a “floating metal” condition (i.e., metal having an unspecified electric potential and effect). In some other implementations, the two layers remain electrically disconnected and are consistently separated by the dielectric layer 35a, or other means. The cap layers 36a-c can reside above and in parallel with the column electrodes (mirror layers) 14a-c.

As indicated by the positions of column interfaces 1103 and row interfaces 1102, the configuration of 1200a requires routing along two separate edges of the array (see, e.g., FIG. 2). Column interfaces 1103 are each in communication with mirror layers 14a-c (the connection itself is hidden from view), while row interfaces 1102 are in communication with electrodes 17a-c (e.g., an electrode within the optical stack, in some implementations, the absorber layer 16b). Thus, routing in this structure is performed in a manner as depicted in FIG. 8A where column and edge routing interfaces are at separate edges.

One implementation for achieving routing along a single edge is shown in the proposed configuration of the array 1200b in FIG. 10B. Here, the configuration 1200b includes row electrodes 17a-c (absorber layer 16b in some implementations), column electrodes 14a-c (e.g., a mirror or reflective layer 14 as depicted in some implementations), and cap layers 36a-c.

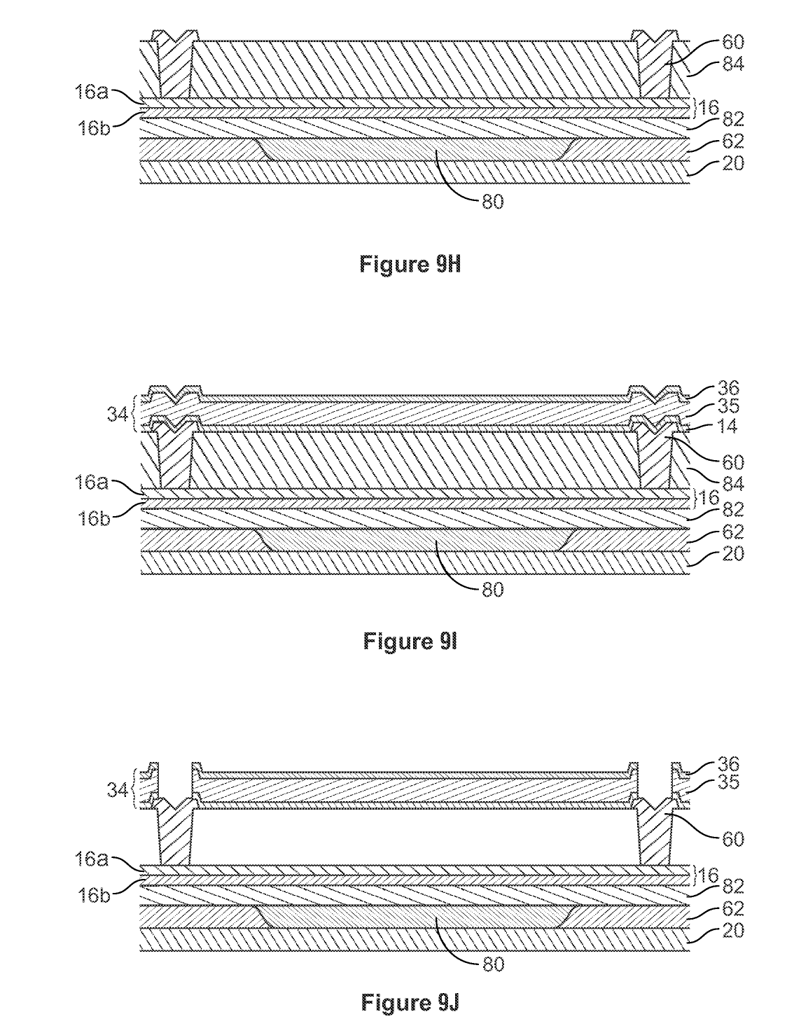

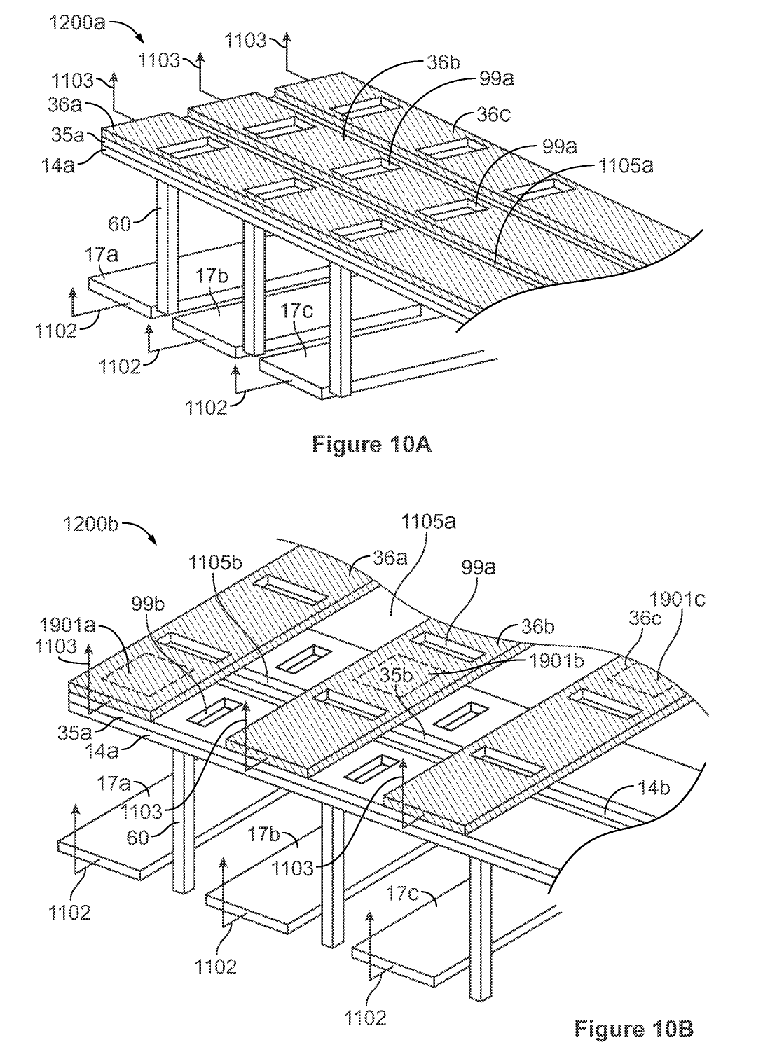

The cap layers 36a-c have been etched to form strips “orthogonal” to the column (mirror) electrodes 14a-c, and are electrically disconnected from the row electrodes 17a-c. Each cap layer 36a-c is connected with a single column electrode 14a-c via intersections/interconnections 1901a-c, respectively. Thus, the cap layer 36a may be used to control column electrode 14a, the cap layer 36b may be used to control column electrode 14b, etc. The intersections 1901a-c may take the form of sacrificed pixel components as described below with regard to FIGS. 12 and 13 (for the purposes of clarity, the exact structure of the intersection, which may comprise an unreleased mechanical layer, is not depicted in FIG. 10B). The rearrangement and reconnection of the cap layers 36a-c can enable the array 1200b to be routed via interfaces 1102 and 1103 along a single edge of rows (as illustrated in FIG. 8B). This is depicted by interfaces 1102 and 1103 being found on the same edge.

In the configuration of 1200b, the cap layers 36a-c can still be configured to have a coefficient of thermal expansion that is substantially similar, or identical, to the mirror layers 14a-c. That is, the dimensions of slots 99a and divisions 1105a in the cap layer may be chosen such that each of cap layers 36a-c continue to complement the thermal expansion of mirror layer 14a (because the slots 99a and divisions 1105a in the cap layer are not drawn to scale, the surface area of the cap layers 36a-c may still cover most of the mirror layer 14a). References 99b and 1105b indicate the slots and divisions, respectively, of the dielectric and mirror layer (in certain implementations slots 99 may only be present in the mirror layer). Slots 99a and 99b are present in some implementations to facilitate the mechanical character of the device, but one would readily recognize that the slots 99 may not be necessary in certain designs. Thus, rather than being aligned parallel with each of mirror layers 14a-c, each cap layer 36a-c may be instead placed orthogonally to the mirror layers, and be connected to a single different mirror layer at a “via” connection 1901a-c, indicated by dashed lines, to route one set of drive signals (e.g., column drive signals) to the mirror layers 14a-c respectively. Thus, in the configuration of 1200b cap layer 36a will be used to control mirror layer 14a through the via at 1901a, cap layer 36b will be used to control mirror layer 14b through the via at 1901b, etc.

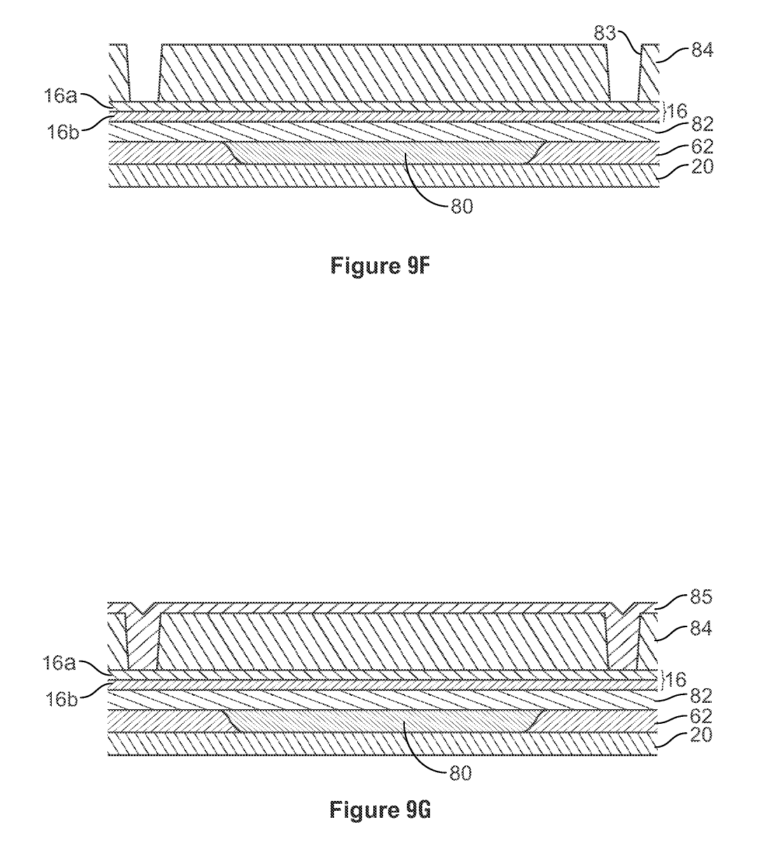

To form the cap layers 36a-c as shown in FIG. 10B, a separate lithographic mask can be used to form the cap, permitting its construction orthogonal to the column electrode. Referring to FIG. 11, the original mask 1400a used to create the cap layer, including slot patterns 1401 and division patterns 1402 for generating the slots 99a and divisions 1105a of FIG. 10A, may be rotated approximately 90° to create a second mask 1400b which will produce orthogonal cap strips. Distinctions between layer formation of configuration 1200a and the formation of 1200b, which uses the modified mask of FIG. 12, are presented in Table 1.

TABLE 1
Relative Formation Steps of Proposed Implementation

| | Formation |
|---|---|
| Formation of Configuration 1200a | of Configuration 1200b |
| 1. Deposit the Mirror and Dielectric layers | 1. Deposit the Mirror layer |
| 2. Etch the Dielectric layer with Mask A if | 2. Etch the Mirror layer with |
| desired, to facilitate connections between | Mask B (1400a) |
| the Mirror and Cap layers to avoid | |
| “floating metal” | |
| 3. Deposit the Cap Layer | 3. Deposit the Dielectric layer |
| 4. Etch each of the Mirror, Dielectric, and | 4. Etch the Dielectric layer |
| Cap layer with Mask B (1400a) | with Mask C, to facilitate |
| | Mirror and Cap connections |
| | 5. Deposit Cap layer |
| | 6. Etch the Cap layer with |
| | Mask D (1400b) |

With reference to Table 1, the configuration 1200a may generally be formed using two masks, but a particular manufacturing process may include additional masks. Mask A is not necessary, but may be used to form holes in the dielectric 35 to facilitate connection between the mirror 14 and cap 36 layers in 1200a, thereby avoiding a “floating metal” condition as described above. Configuration 1200b, in contrast, makes use of at least three separate masks (although Mask D may merely be a 90° rotation of Mask B as previously indicated in FIG. 11). Mask B 1400a may be again used to form the mirror layer (as it was used in the configuration 1200a), but Mask C is instead used, rather than Mask A to form the portion of interconnects 1901a-c in the dielectric material. These interconnects may not be the same as in 1200a in many implementations, hence the need for a different mask from Mask A. Mask D 1400b is then used to etch the cap layer in the orthogonal orientation depicted in FIG. 10B.

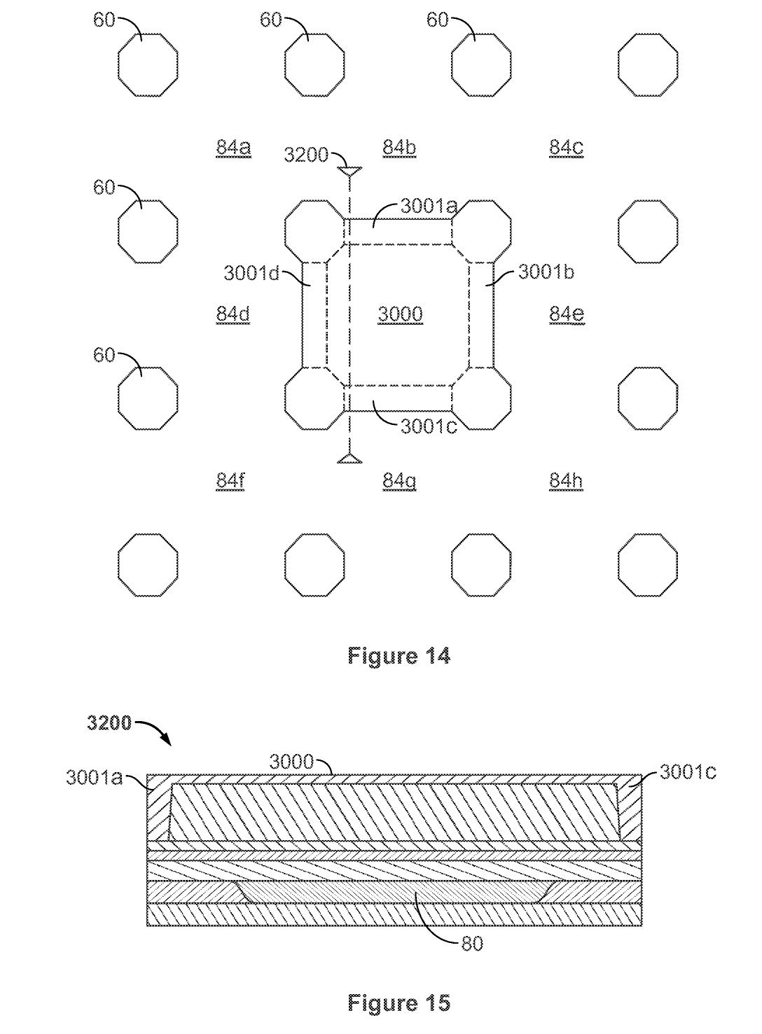

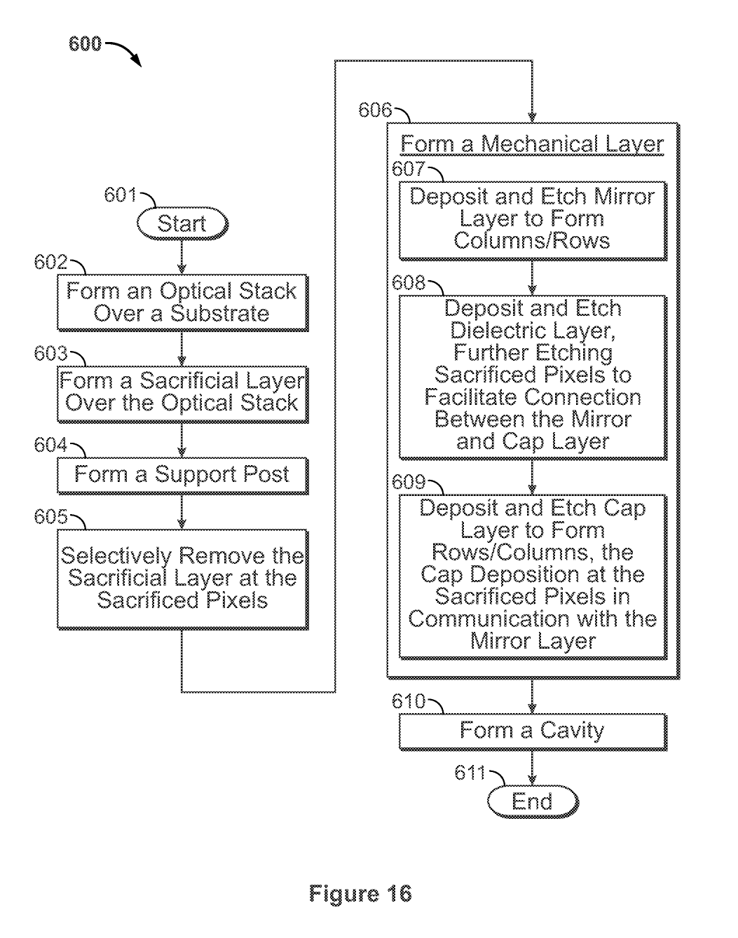

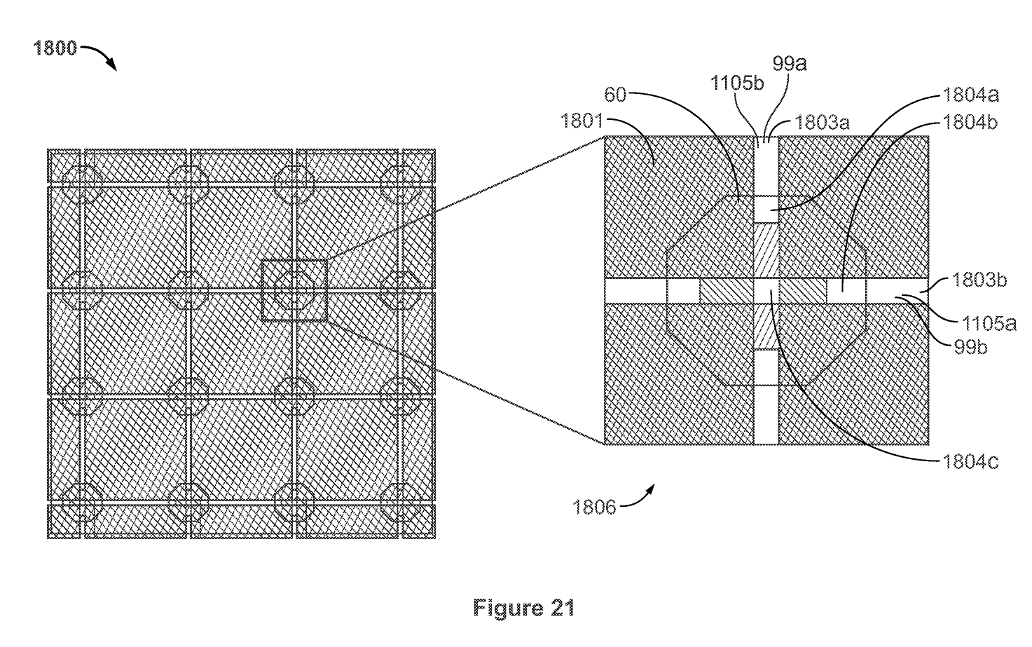

The masking process may be modified in accordance with the methods described in FIGS. 16, 17, and 20. For example, the masks used in the process of FIG. 16 may be modified relative to those used in the process of FIG. 17, to avoid damaging the protective post material layer described with respect to 605b. The masks may be further modified to minimize post attack described below with respect to FIG. 21.

As was mentioned with regard to FIG. 10B, intersections 1901a-c facilitate electrical communication between the column electrodes 14a-c and the interfaces 1103 along the edge. At these interfaces, it may be preferable to prevent the mechanical layer from moving, so as to ensure a secure electrical connection. That is, during formation of the mechanical layer (in relation to FIGS. 9I and 9J above), those pixels which will become one of intersections 1901a-c are instead sacrificed (i.e., rendered inoperable) and formed as shown in either FIG. 12 or 13. In each of FIGS. 12 and 13, the intervening dielectric 35 is etched such that the cap layer 36 will be in communication with the mirror layer 14 upon deposition to form an interconnect such as 1901a. This will facilitate the electrical communication to control column electrode 14 via electrical signals placed on cap 36.

In FIG. 12, the sacrificial layer 84 at the interconnect pixel may be etched away during formation, e.g., at FIG. 9F. By removing the sacrificial layer 84, subsequent depositions will reside atop the optical stack 16. In these implementations, the dielectric layer 16a of the optical stack 16 may prevent direct electrical communication between the mirror layer 14 and optical stack electrode 16b.

Alternatively, the sacrificial layer may be retained, as shown in FIG. 13, to render the interconnecting pixel immobile. Among other benefits, the immobile mechanical layer 34 helps ensure that the connection between the cap layer 36 and mirror layer 14 is maintained. A partially fabricated interferometric modulator that contains a sacrificial layer 84 may be referred to herein as an “unreleased” interferometric modulator. Again, as was mentioned above, FIG. 10B does not depict certain details of the interconnects 1901a-c for purposes of clarity. Rather the presence of an interconnect or via 1901 is indicated with a dashed square.

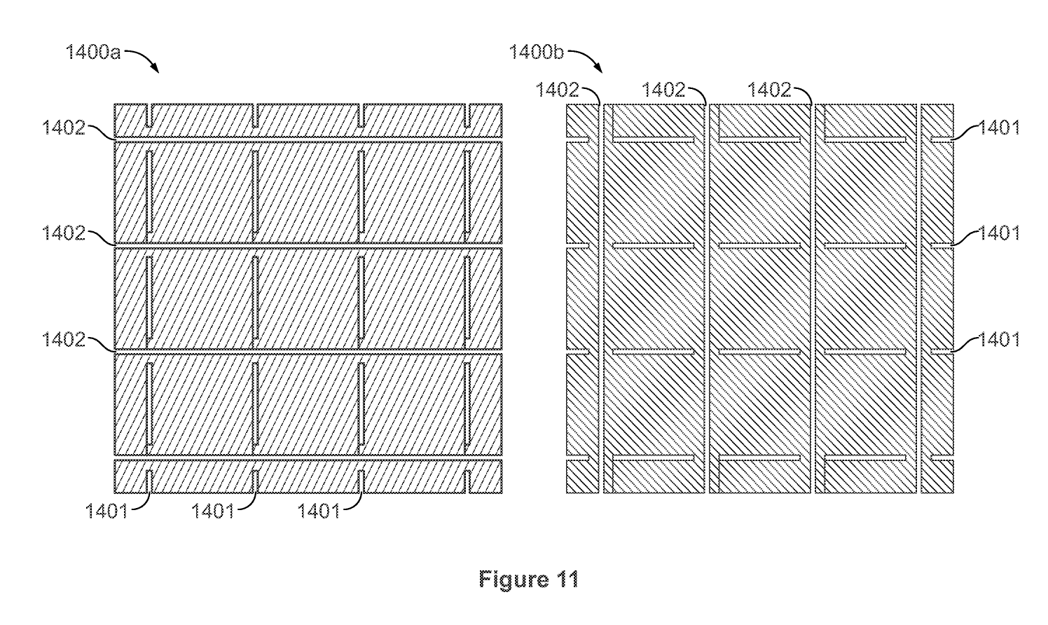

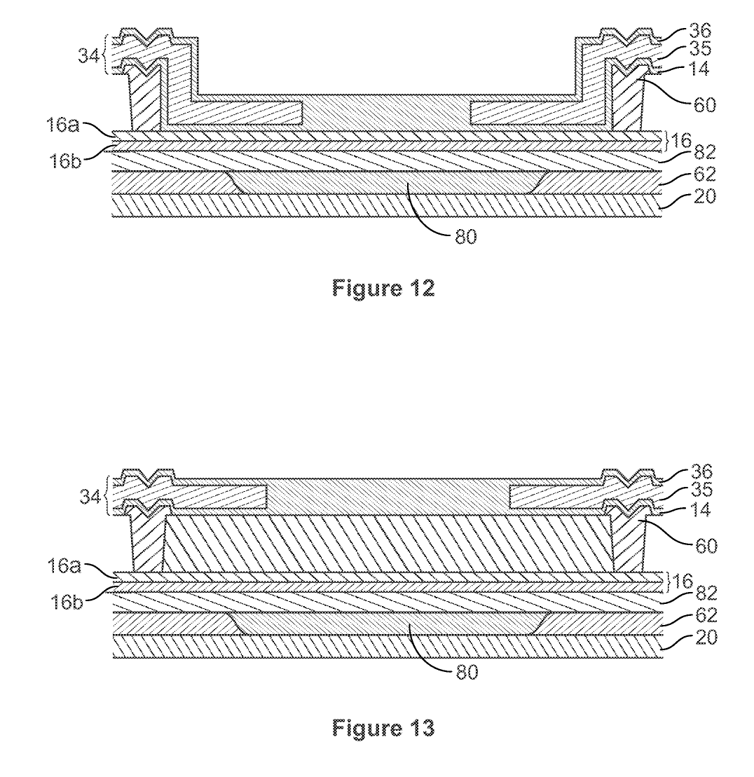

Previously, with regard to FIG. 9J, it was explained that the sacrificial layer 84 was removed throughout the array. The structure of FIG. 13 retains its sacrificial layer despite this step. FIGS. 14 and 15 clarify one possible implementation for accomplishing this objective. During formation of the post recesses in FIG. 9H, a subsequent etching, using a new mask, may be performed so as to produce a “moat” or “trench” 3001a-d within the sacrificial material. These trenches will be located around a pixel at which an interconnect will be formed (location 3000 in FIG. 14). This region is subsequently filled with support material 85 when creating posts 60 about each of device elements 84a-h (FIG. 15 illustrates this filling in trenches 3001a and 3001c via cross-section 3200). The post, or support, material 85 is retained in this area during subsequent depositions and protects the sacrificial layer at the interconnect, while the sacrificial layer is removed elsewhere. In the resulting interconnect 1901, a layer of post material 85 would appear beneath the mirror layer 14 (although this is not shown in FIG. 13). The elements at locations 84a and 84h might similarly be encapsulated with protective post material to preserve the sacrificial layer. For clarity, only region 3000 is presently indicated.

FIG. 16 is a flow chart illustrating one implementation of a manufacturing process for an interferometric modulator array as shown in FIGS. 9A-9J, with interconnects as shown in FIG. 12. FIG. 16 illustrates one implementation of a manufacturing process 600 for an array of optical modulators, such as interferometric modulators. In this process, interconnects, such as are shown in FIG. 12, may be formed. It will be understood that not all of the illustrated steps are required, and that this method can be modified without departing from the spirit and scope of this disclosure. These steps may be present in a process for manufacturing, for example, with any of the interferometric modulators illustrated in FIGS. 1 and 7A-7E.

With reference to FIGS. 9A-9J, the process 600 begins 601 by forming 602 a stationary electrode such as the absorber layer 16b found in the optical stack 16 over the substrate 20. The substrate 20 can be any transparent substrate, and can include, e.g., glass or plastic. Although the process 600 is illustrated as starting at 601, the substrate 20 can be subjected to one or more prior preparation steps, such as, a cleaning step to facilitate efficient formation of the optical stack 16. Additionally, in some implementations, one or more layers can be provided before forming the optical stack 16 over the substrate 20. For example, with reference to FIG. 9B, in one implementation, the black mask 62 can be provided, formed or deposited, before forming the optical stack 16. The optical stack 16 for an interferometric modulator can be electrically conductive, partially transparent and partially reflective, and can be fabricated, for example, by depositing one or more of the layers onto the transparent substrate 20. The optical stack 16 also can include an insulating or dielectric layer 16a covering conductive layer(s) 16b. In some implementations, the one or more layers can be patterned into parallel strips, and may form row electrodes in a display device. As used herein, the term “patterned” can refer to masking as well as etching processes. “Forming” will similarly be understood the mean deposition and etching to form the structure.

In block 603, a sacrificial layer can be formed over the optical stack 16. The sacrificial layer can later be removed to form a gap (e.g., gap 19 depicted in FIG. 1). Accordingly, the sacrificial layer is not shown in the resulting interferometric modulator illustrated in FIG. 1. The formation of the sacrificial layer over the optical stack 16 may include deposition of a fluorine-etchable material such as molybdenum (Mo) or amorphous silicon (Si), in a thickness selected to provide, after subsequent removal, a gap 19 having the desired size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

In block 604, a support structure can be formed, such as the support post 60. The formation of the support post 60 may include the steps of patterning the sacrificial layer to form a support structure aperture, then depositing a material (e.g., a polymer or a silicon oxide) into the aperture using a deposition method such as PECVD, thermal CVD, or spin-coating. In some implementations, the support structure aperture formed in the sacrificial layer extends through both the sacrificial layer and the optical stack 16 to the underlying substrate 20, so that the lower end of the support post 60 contacts the substrate 20. In other implementations, the aperture formed in the sacrificial layer can extend through the sacrificial layer, but not through the optical stack 16. For example, FIG. 7C illustrates the lower end of the plugs 42 in contact with the optical stack 16. In FIG. 7B, the post 18 contacts the substrate 20.

In block 605, the sacrificial layer can be removed at the intersection pixels to immobilize the mechanical layer. This may occur, for example, at the steps illustrated in either FIG. 9F or 9H where the sacrificial layer is exposed. This will permit formation of interconnects 1901 as are shown in FIG. 12.

The process 600 continues to block 606 with the formation of a mechanical layer such as the mechanical layer 34 illustrated in FIG. 9I. The mechanical layer 34 can be formed by employing one or more deposition steps, e.g., reflective layer (e.g., aluminum, aluminum alloy) deposition, along with one or more patterning, masking, and/or etching steps. Certain of these steps relevant to the implementations of FIG. 10 are discussed in 607-609. Portions of the mechanical layer 34 can be electrically conductive, and in some implementations may serve as the moveable electrode (e.g., in FIG. 7A the illustrated moveable reflective layer 14 is the mechanical layer). In some other implementations, another layer besides the mechanical layer 34 can serve as the moveable electrode, such as, the moveable reflective layer 14 in FIG. 7D. Since the sacrificial layer is still present in many of the partially fabricated interferometric modulators at block 605 of the process 600, the mechanical layer 34 is typically not moveable at this stage.

Formation of the mechanical layer further includes etching the mirror layer to form columns or rows in block 607. Subsequently, in block 608, the dielectric layer 35 is deposited and etched, and the sacrificed pixels further etched to facilitate connection between the mirror and cap layer (as shown in FIGS. 12 and 13). At block 609, the cap layer is deposited and etched to form strips orthogonal to the mirror layer 14. At the sacrificed pixels, where the dielectric 35 was removed, the cap deposition will be in electrical communication with the mirror layer 14.

After forming the mechanical layer 34, the gap 19, or cavity, between the mechanical layer 34 and substrate 20, e.g., the gap 19 illustrated in FIG. 1, is formed 610. The gap 19 may be formed by exposing the sacrificial material, such as the sacrificial material deposited in block 603, to an etchant. For example, an etchable sacrificial material such as Mo, tungsten (W), tantalum (Ta), polycrystalline, or amorphous silicon may be removed by dry chemical etching, for example, by exposing the sacrificial layer to a fluorine-based gaseous or vaporous etchant, such as vapors derived from solid xenon di-fluoride (XeF₂). As skilled artisans will recognize, the sacrificial layer can be exposed for a period of time that is effective to remove the material, typically selectively relative to the structures surrounding the gap 19. Other selective etching methods, for example, wet etching and/or plasma etching, also can be used. Since the sacrificial layer is removed after block 606, the moveable reflective layer 14 and/or mechanical layer 34 can be released, and the mechanical layer 34 can become displaced from the substrate 20 by a launch height, e.g., due to mechanical stress. The resulting fully or partially fabricated interferometric modulator may be referred to herein as a “released” or “launched” interferometric modulator. The illustrated process 600 ends at 611. The skilled artisan will readily appreciate that many additional steps may be employed before, in the middle of, or after the illustrated sequence, but are omitted for simplicity.

FIG. 17 is a flow chart illustrating one implementation of a manufacturing process for an interferometric modulator array as shown in FIGS. 9A-9J, with interconnects as shown in FIG. 13. FIG. 17, like FIG. 16, illustrates a manufacturing process 600 to create an array which may be routed from a single edge. The process of FIG. 17, however, employs the formation of interconnects as are illustrated in FIG. 13. Blocks 601-603 are the same as was described in FIG. 16. However, at block 604b, the protective “moats” or “trenches” in the sacrificial layer, as described with respect to FIGS. 14 and 15 are formed. During subsequent deposition of the post material at block 605b, the trenches are filled with post material, providing a protective encapsulation of the sacrificial layer beneath the movable layer (again, for purposes of clarity the top of the protective layer is omitted from FIG. 13). The remaining blocks 606-611 are the same as was described with respect to FIG. 16.

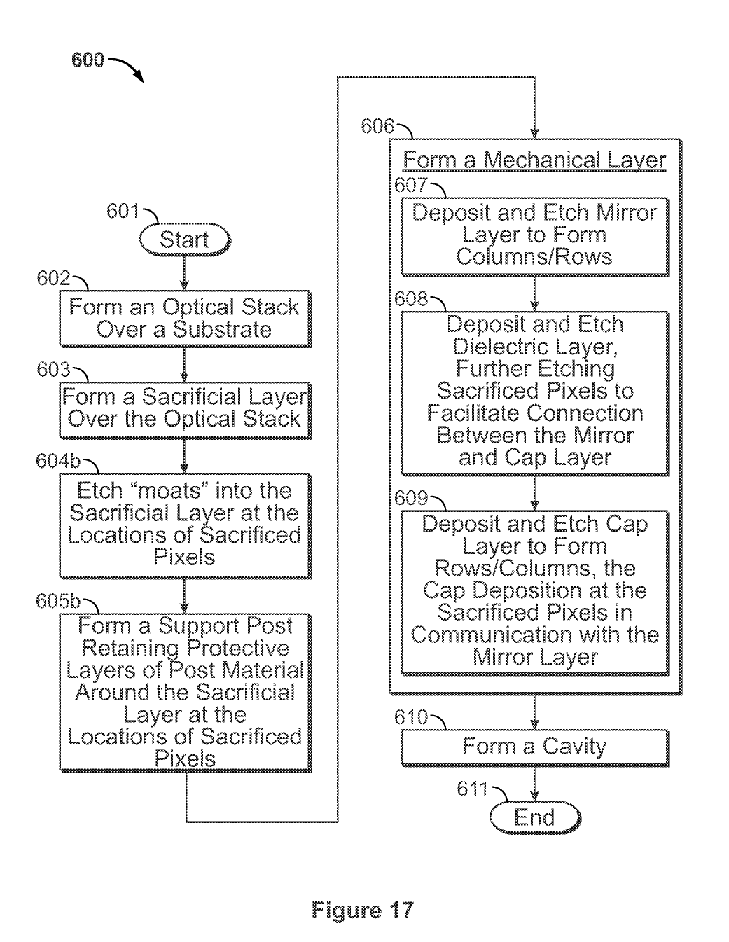

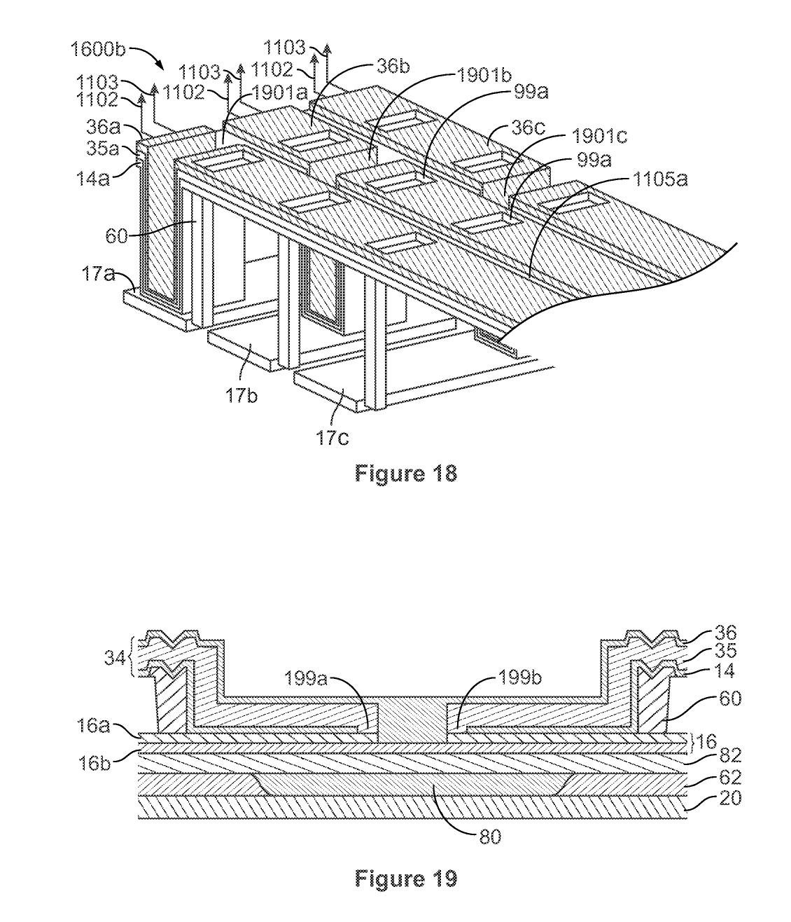

FIG. 18 is a perspective schematic of a portion of an interferometric array illustrating a second implementation for routing along a single edge, wherein the cap layers 36a-c are in communication with fixed electrodes 17a-c respectively. Here, the cap layers 36a-c, retain their original orientation but are instead configured so as to facilitate “row” routing from a single edge of columns. In configuration 1600b, unlike the configuration 1200b of FIG. 10B, the cap layers 36a-c are not in electrical communication with the “column” mirror electrodes 14a-c (e.g., the mirror, or reflective layer), wherein the cap layer and mirror layer form two separate electrical lines. Instead, each cap layer 36a-c is connected to a fixed “row” electrode at intersections 1901a-c. While these connections are generally indicated in FIG. 18, the details of the interconnection are provided in FIG. 19. The row control interface 1102 can now reside on the same side as the column control interface 1103, while providing access to the orthogonal row electrode via the cap layers 36a-c. The mirror layer and the cap layer may each be used to route a row or column drive signal and, because they are aligned, the interface for these layers will reside along the same edge of the array. Thus, in FIG. 19, cap layer 36a would control row electrode 17a, cap layer 36b would control row electrode 17b, etc. This configuration can economize peripheral space and reduce the number of routing components within the array. Again, unlike the sacrificed modulators shown in FIGS. 12 and 13, the intersections 1901a-c shown in FIG. 18 connect the cap layer 36 to the electrode in the optical stack 16 (in this implementation, the cap layer 36 is in electrical communication with optical absorber 16b), rather than to the mirror layer 14.

FIG. 19 shows a schematic cross-section illustrating an implementation of the interconnection between the cap layer 36 and the fixed electrode 16b shown at 1901a in FIG. 10A with a via through the dielectric and mirror layers (for clarity, FIG. 18 does not attempt to show these details at the point of connection between the mirror and electrode). Particularly, FIG. 19 illustrates a sacrificed interferometric modulator, which provides an intersection 1901a with a via between the “row” electrode and cap layer. Here, the sacrificial layer 84 is again selectively removed at any of FIG. 9E, 9F, or 9H so that the interferometric modulators forming intersections are immobilized. Furthermore, the optical stack dielectric 16a is etched to facilitate connection between the cap layer 36 and the absorber layer electrode 16b. The mirror layer 14 is further etched to create spacings 199a-b to prevent contact between the cap layer 36 protrusion and mirror layer 14. Though spacings 199a-b are shown here as including the dielectric layer 35, a person having ordinary skill in the art will readily recognize that a number of intervening materials may be used, such as sacrificial material from sacrificial layer 84 which has not been etched away, or a specially prepared insulating deposition. Furthermore, one would readily recognize that FIG. 19 represents a cross-section of the device, and that the mirror layer 14 remains continuous around the intervening protrusion of cap layer 36 material. Thus, the structure facilitates connection between the cap layer 36 and the electrode 16b of the optical stack 16. A person having ordinary skill in the art may recognize that forming a via through the post 60 also could facilitate the connection. One would readily recognize numerous variations in the above implementation, which will successfully immobilize the interconnect. The sacrificial layer may be retained, for example, in a manner not unlike that described in relation to FIG. 13, and a corresponding structure generated.

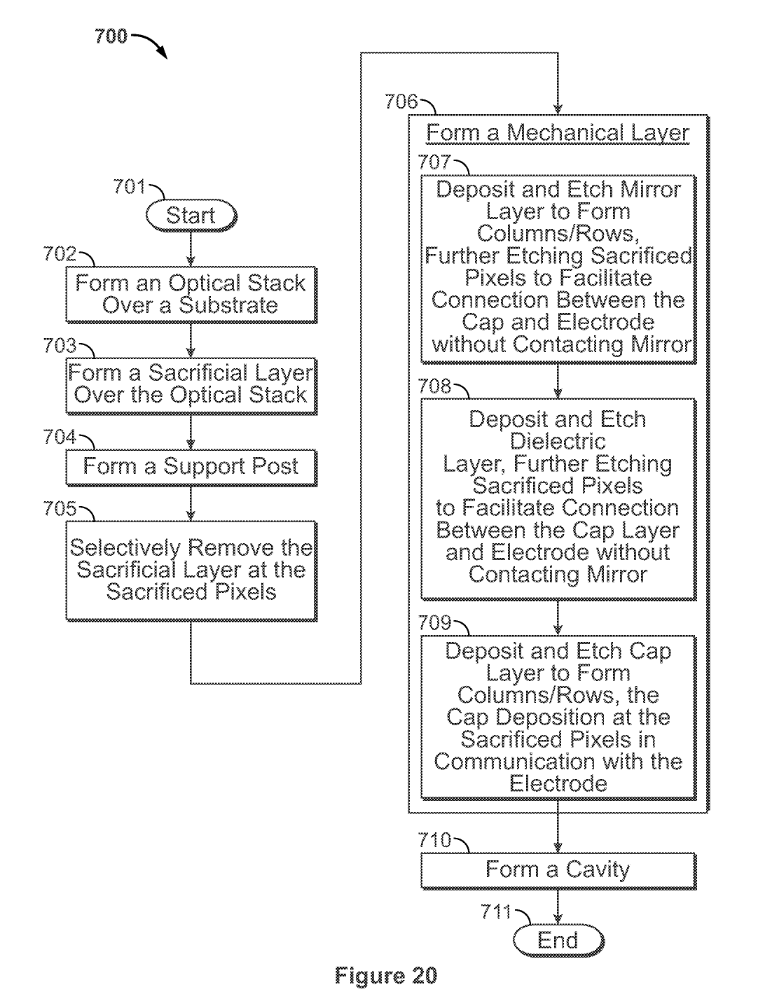

FIG. 20 is a flow chart illustrating one implementation of a manufacturing process for an interferometric modulator array as shown in FIG. 18, with interconnects as shown in FIG. 19. Blocks 701-705 may be similar to blocks 601-605 discussed above with respect to FIG. 16. In some implementations, the dielectric 16a surrounding the electrode 16b in the optical stack 16, can be removed, at either block 702 or after block 705, from the intersection pixels to facilitate connection with the cap layer to the electrode as depicted in FIG. 19. During formation of the mechanical layer at block 706, the mirror layer can be deposited and etched to form parallel strips. Additionally, at block 707, for those modulators which will include intersections, the mirror layer can be further etched to avoid contact with the descending cap layer (i.e., spacings 199a-b). An insulating material also may be subsequently deposited at these modulators to further ensure separation. The dielectric can then be deposited and etched at block 708 to shape the patterning into mirror layer 14 and cap layer 36 strips (in FIG. 18, the mirror 14a-c and cap 36a-c layer strips are in parallel). At block 709, the cap layer is deposited and etched to form columns and rows. The cap layer deposition can cause the sacrificed pixels to be in communication with the electrode 16b of the optical stack 16. The sacrificial layer under the remaining modulators can be removed to form cavities at block 710 and the array can be completed at block 711. Additional steps, such as connecting the array to the edge interface, or the reordering of depositions to require the use of fewer masks are omitted for the sake of clarity.

Rearrangement of the cap layer may affect etching at post positions. This may result in portions of the post being unfavorably “attacked” during etching. Certain implementations contemplate etching with an additional mask to facilitate proper post construction. FIG. 21 illustrates a top-down view 1800 of the resulting display after such a mask is employed. Magnified post region 1806 illustrates the relationship between the cap and mirror layers over post 60. Region 1803a indicates the division 1105b (see FIG. 10B) where the reflective layer is separated and the cap layer slot 99a is cut. Region 1803b indicates the position of the complementary cap layer separation 1105a and mirror metal slot 99b. Regions 1804a-c indicate portions of the hexagonal post 60 which are not protected by either the cap or mirror layers and are therefore subject to post attack (without etch stop).

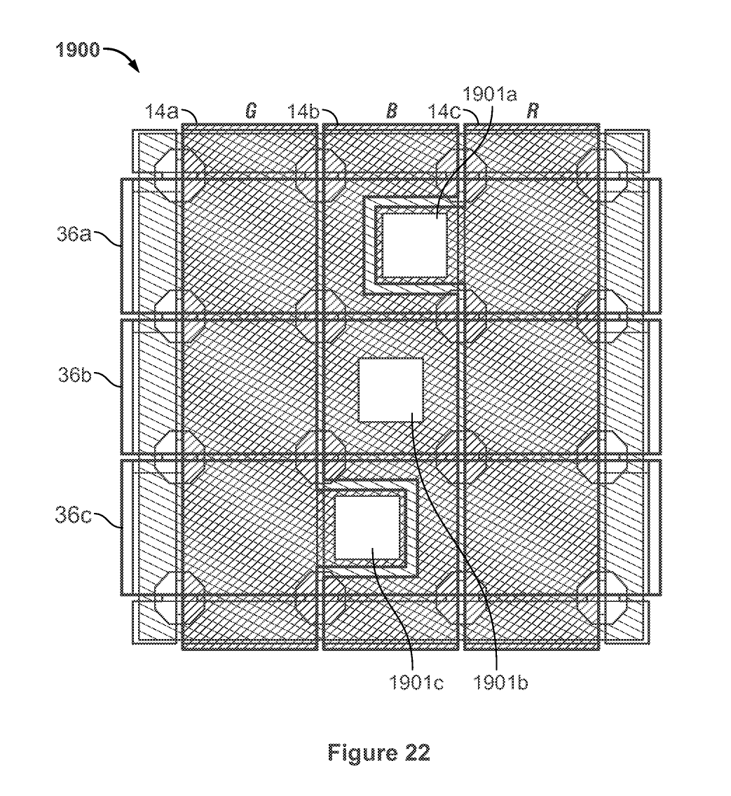

FIG. 22 illustrates a top-down perspective view of an alternative routing configuration at intersections 1901a-c in the configuration 1200b found in FIG. 10B (again, not all layers are shown for ease of comprehension). This three element by three element subarray may comprise a single “pixel” in certain implementations. Each of Mirror layers 14a, 14b, and 14c has a distinct launch height such that elements along the length of 14a produces a green “G” color, 14b a blue “B”, and 14c a red “R” color. As previously discussed with respect to 1200b, the cap layers 36a-c are orthogonal to the mirror (or reflective) layers 14a-c.

In some implementations, a viewer will more readily discern disruptions in the “lighter” red and green components of the pixel. Accordingly, if elements in the subarray were sacrificed to facilitate interconnections across a diagonal from the upper left, to lower right, a red and green component would be destroyed, possibly creating a visible defect in the display quality. Instead, it may be preferable to sacrifice only darker subcomponents, such as the blue components, the consequence of which is less readily visible.

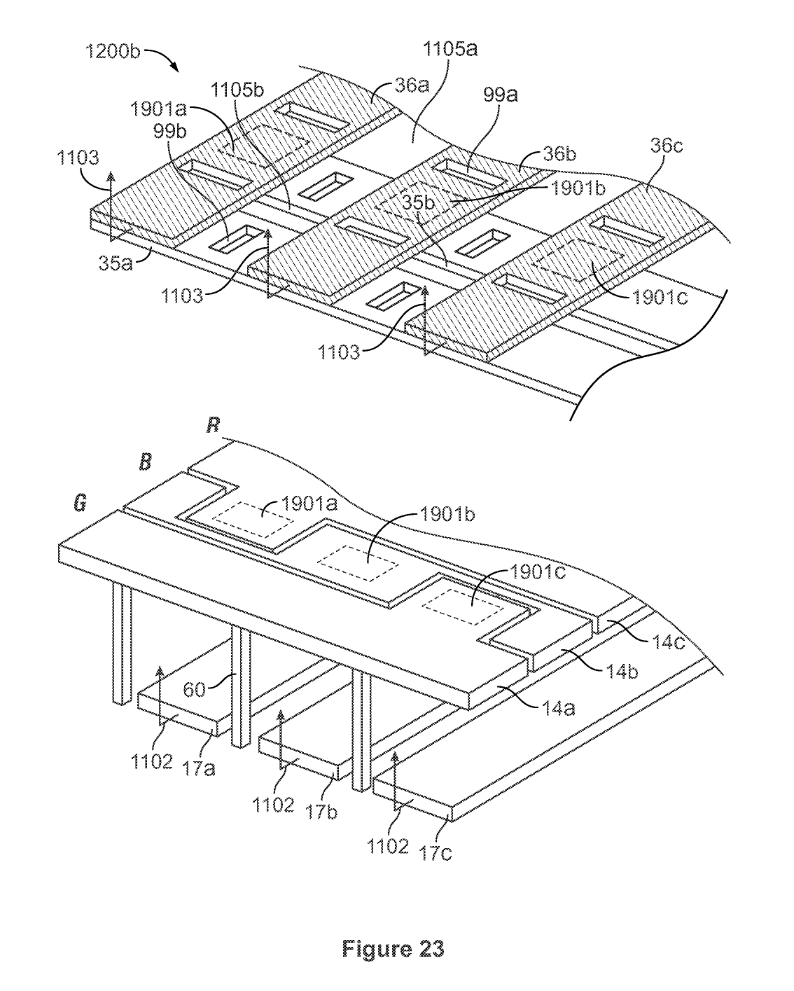

To facilitate sacrifice of only the blue components, the mask for generating the reflective layer may be modified, such that the mirror layers 14a-c are etched as shown in FIG. 22 (and isometrically for clarity in FIG. 23). In this manner, reflective layers 14a and 14c acquire extensions, and layer 14b acquires recesses to accommodate these extensions. Through the extension, mirror layer 14a is in communication with cap layer 36c through via 1901c. Reflective layers 14b and 14c are similarly placed in communication with cap layers 36b and 36a, through vias 1901b and 1901a, respectively. In this implementation, reflective layer 14a may thereby be activated via an interface in communication with cap layer 36c, 14b by 36b, and 14c by 36a.

FIG. 23 illustrates a perspective view schematic of the proposed routing structure of the intersection of FIG. 22, wherein the dielectric 35a-b and cap 36a-c layers are “raised up” to more clearly illustrate the structure of the mirror layers 14a-c. Although the mirror layer 14b is here used to display the blue component, one will readily recognize that had the launch heights been so created that elements along the length of cap layer 36b instead represented the blue components, a patterning among cap layers 36a-c could be employed in a fashion analogous to that employed for the mirror layers 14a-c in FIG. 23 to facilitate sacrifice of only blue components.

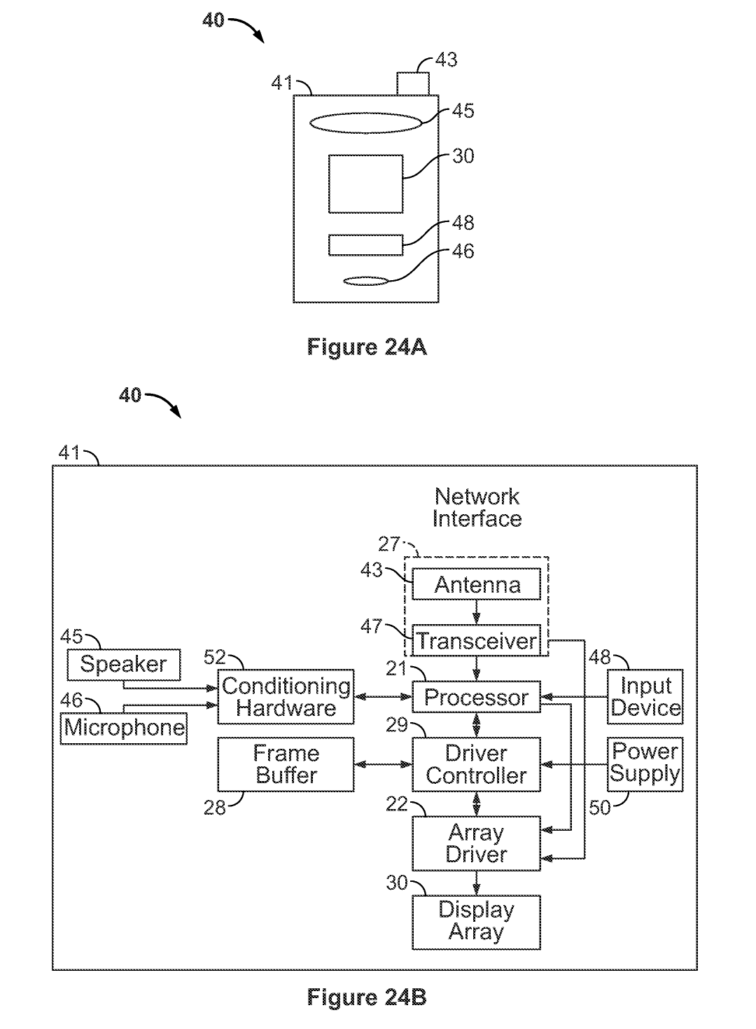

FIGS. 24A and 24B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 24B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device, comprising:
an array having a plurality of electromechanical elements arranged in columns and rows, the array comprising:
a plurality of fixed electrodes, each fixed electrode spanning a row of electromechanical elements of the array and forming a portion of the electromechanical elements that the fixed electrode spans;
a plurality of first movable electrodes, each first movable electrode spanning a column of electromechanical elements of the array and forming a portion of the electromechanical elements that the first movable electrode spans;
a plurality of second movable electrodes, each second movable electrode spanning a row of electromechanical elements of the array and forming a portion of the electromechanical elements the second movable electrode spans, and each second movable electrode electrically connected to at least one first movable electrode; and
a dielectric layer between at least a portion of the first movable electrodes and at least a portion of the second movable electrodes;
a row signal interface to provide drive signals to rows of electromechanical elements in the array, the row signal interface disposed along a first side of the array, the row signal interface in communication with the plurality of fixed electrodes; and
a column signal interface to provide drive signals to columns of electromechanical elements in the array, the column signal interface disposed along the first side of the array, the column signal interface in communication with the plurality of second movable electrodes.

2. The device of claim 1, wherein the electromechanical device is an interferometric modulator.

3. The device of claim 1, wherein each second movable electrode is aligned orthogonal to each first movable electrode.

4. The device of claim 1, wherein each second movable electrode is electrically connected to at least one first movable electrode through a via in a portion of a sacrificed pixel.

5. The device of claim 1, wherein the thermal coefficient of expansion of the substrate is substantially the same as the thermal coefficient of expansion of at least one of the first movable electrode, dielectric layer, and second movable electrode.

6. The device of claim 1, further comprising:
a display;
a processor that is configured to communicate with the display, the processor being configured to process image data; and
a memory device that is configured to communicate with the processor.

7. The device of claim 6, further comprising a driver circuit configured to send at least one signal to the display.

8. The device of claim 7, further comprising a controller configured to send at least a portion of the image data to the driver circuit.

9. The device of claim 6, further comprising an image source module configured to send the image data to the processor.

10. The device of claim 9, wherein the image source module comprises at least one of a receiver, transceiver, and transmitter.

11. The device of claim 6, further comprising an input device configured to receive input data and to communicate the input data to the processor.

12. A device, comprising:
an array having a plurality of electromechanical elements arranged in columns and rows, the array comprising:
a plurality of fixed electrodes, each fixed electrode spanning a row of electromechanical elements of the array and forming a portion of the electromechanical elements that the fixed electrode spans;
a plurality of first movable electrodes, each first movable electrode spanning a column of electromechanical elements of the array and forming a portion of the electromechanical elements that the first movable electrode spans;
a plurality of second movable electrodes, each second movable electrode spanning a column of electromechanical elements of the array and forming a portion of the electromechanical elements the second movable electrode spans, and each second movable electrode electrically connected to at least one fixed electrode; and
a dielectric layer between at least a portion of the first movable electrodes and at least a portion of the second movable electrodes;
a column signal interface to provide drive signals to columns of elements in the array, the column signal interface disposed along a first side or the array, the column signal interface in communication with the plurality of first movable electrodes; and
a row signal interface to provide drive signals to rows of elements in the array, the row signal interface disposed along the first side of the array, the row signal interface in communication with the plurality of second movable electrodes.

13. The device of claim 12, wherein the electromechanical device is an interferometric modulator.

14. The device of claim 12, wherein each second movable electrode is aligned parallel to each first movable electrode.

15. The device of claim 12, wherein each second movable electrode is electrically connected to at least one fixed electrode through a via in the dielectric layer.

16. The device of claim 12, wherein each second movable electrode is electrically connected to at least one fixed electrode through a via in the dielectric and first movable layers.

17. The device of claim 12, wherein the first plurality of movable electrodes are not in electrical communication with any of the second plurality of movable electrodes.

18. The device of claim 12, wherein the thermal coefficient of expansion of a substrate is substantially the same as the thermal coefficient of expansion of at least one of a first movable electrode, dielectric layer, and second movable electrode.

19. An electromechanical device, comprising:
a fixed electrode forming a portion of the electromechanical device, the fixed electrode in communication with a row signal interface disposed along a first side of the array;
a first movable electrode forming a portion of the electromechanical device;
a second movable electrode forming a portion of the electromechanical device, the second movable electrode electrically connected to the first movable electrode, the second movable electrode in communication with a column signal interface disposed along the first side of the array; and
a dielectric layer between at least a portion of the first movable electrode and at least a portion of the second movable electrode.

20. The device of claim 19, wherein the electromechanical device is an interferometric modulator.

21. The device of claim 19, wherein each second movable electrode is aligned orthogonal to each first movable electrode.

22. The device of claim 19, wherein each second movable electrode is electrically connected to at least one first movable electrode through a via in a portion of a sacrificed pixel.

23. The device of claim 19, wherein the thermal coefficient of expansion of a substrate is substantially the same as the thermal coefficient of expansion of at least one of a first movable electrode, dielectric layer, and second movable electrode.

24. An electromechanical device, comprising:
a first fixed means for conducting forming a portion of the electromechanical device, the fixed conducting means further in communication with a first means for interfacing along a first side of a means for displaying;
a first movable means for conducting forming a portion of the electromechanical device;
a second movable means for conducting forming a portion of the electromechanical device, and the second movable conducting means electrically connected to the first movable conducting means, the second movable conducting means further in communication with a second signal interface along the first side of the displaying means; and
a means for electrical insulation between at least a portion of the first movable conducting means and at least a portion of the second movable conducting means.

25. The device of claim 24, wherein the electromechanical device is an interferometric modulator.

26. The device of claim 24, wherein each second movable conducting means is aligned orthogonal to each first movable means.

27. The device of claim 24, wherein each second movable conducting means is electrically connected to at least one first movable conducting means through a via in a portion of a sacrificed pixel.

28. The device of claim 24, wherein the thermal coefficient of expansion of a substrate is substantially the same as the thermal coefficient of expansion of at least one of the first movable conducting means and the second movable conducting means.

29. A method of manufacturing an edge-controlled display comprising:
providing a substrate;
providing a first interface along a side of the display;
providing a second interface along the side of the display;
forming a fixed electrode layer over the substrate and etching the first fixed electrode layer to form a plurality of electrically separate strips of the fixed electrode layer wherein the plurality of electrically separate strips are in electrical communication with the first interface;
forming posts extending above the first fixed electrode;
forming a first movable electrode layer over the posts, comprising etching a plurality of electrically separate strips of the first movable electrode layer;
forming a dielectric layer over the first movable electrode layer, comprising etching vias through the dielectric layer; and
forming a second movable electrode layer over the dielectric layer, comprising etching a plurality of electrically separate strips of the second movable electrode layer, wherein each of the plurality of electrically separate strips of the second movable layer are separately in electrical communication with an electrically separate strip of the first movable electrode and with the second interface.

30. The method of claim 29, wherein the plurality of electrically separate strips of the second movable electrode layer is substantially orthogonal to the plurality of electrically separate strips of the first movable electrode layer.

31. The method of claim 29, wherein forming the movable electrode layer comprises forming extensions and recesses, the extensions in communication with at least one via.

32. A method of manufacturing an edge-controlled display comprising:
providing a substrate;
providing a first interface along a side of the display;
providing a second interface along the side of the display;
forming a fixed electrode layer over the substrate and etching the first fixed electrode layer to form a plurality of electrically separate strips of the fixed electrode layer;
forming posts extending above the first fixed electrode;
forming a first movable electrode layer over the posts, comprising etching a plurality of electrically separate strips of the first movable electrode layer, the electrically separate strips of the first movable layer in electrical communication with the second interface;
forming a dielectric layer over the first movable electrode layer; and
forming a second movable electrode layer over the dielectric layer, comprising etching a plurality of electrically separate strips of the second movable electrode layer, wherein each of the plurality of electrically separate strips of the second movable electrode layer are separately in electrical communication with an electrically separate fixed electrode strip and in electrical communication with the first interface.

33. The method of claim 29, wherein a first mask used to etch the plurality of electrically separate strips of the first movable electrode layer is different from a second mask used to etch the plurality of electrically separate strips of the second movable electrode layer.

34. The method of claim 31, wherein the first mask produces extensions and recesses in the first movable electrode layer.
